(19) United States
(12) Patent Application Publication
(10) Pub. No.: US 2026/0129825 A1
(43) Pub. Date: May 7, 2026

(54) Memory Circuitry And Methods Used In Forming Memory Circuitry

(71) Applicant: Micron Technology, Inc., Boise, ID (US)

(72) Inventors: Pavani Vamsi Krishna Nittala, Meridian, ID (US); Yuichi Yokoyama, Boise, ID (US); Brenda Li, Boise, ID (US); Muralikrishnan Balakrishnan, Boise, ID (US); Kolya Yastrebenetsky, Boise, ID (US)

(73) Assignee: Micron Technology, Inc., Boise, ID (US)

(21) Appl. No.: 19/324,370

(22) Filed: Sep. 10, 2025

Related U.S. Application Data
(60) Provisional application No. 63/715,845, filed on Nov. 4, 2024.

(51) Int. Cl. H10B 12/00

(52) U.S. Cl. CPC H10B 12/30; H10B 12/03; H10B 12/05

(57) ABSTRACT

Memory circuitry comprises an integrated circuit die comprising a radially-outermost region surrounding a radially-inner region. The inner region comprises a memory-array region. The radially-outermost region comprises a lower semiconductor material, insulative material directly above the lower semiconductor material, and a stack comprising alternating tiers of different composition semiconductive materials directly above the insulative material. A conductive-wall construction is in the radially-outermost region at least partially surrounding the inner region. Other embodiments, including methods, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including essentially horizontally in a single plane or alternately, for example, in a vertical stack (e.g., along a z direction) comprising a three-dimensional (3D) memory-array region having horizontal tiers in which individual memory cells are received (e.g., arrayed in x and y directions). The stack in the 3D memory-array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-41 are diagrammatic sequential sectional and/or enlarged views of a construction, or portions thereof or alternate and/or additional embodiments, in process in accordance with some embodiments of the invention.

### DETAILED DESCRIPTION OF EXAMPLE EMBODIMENTS

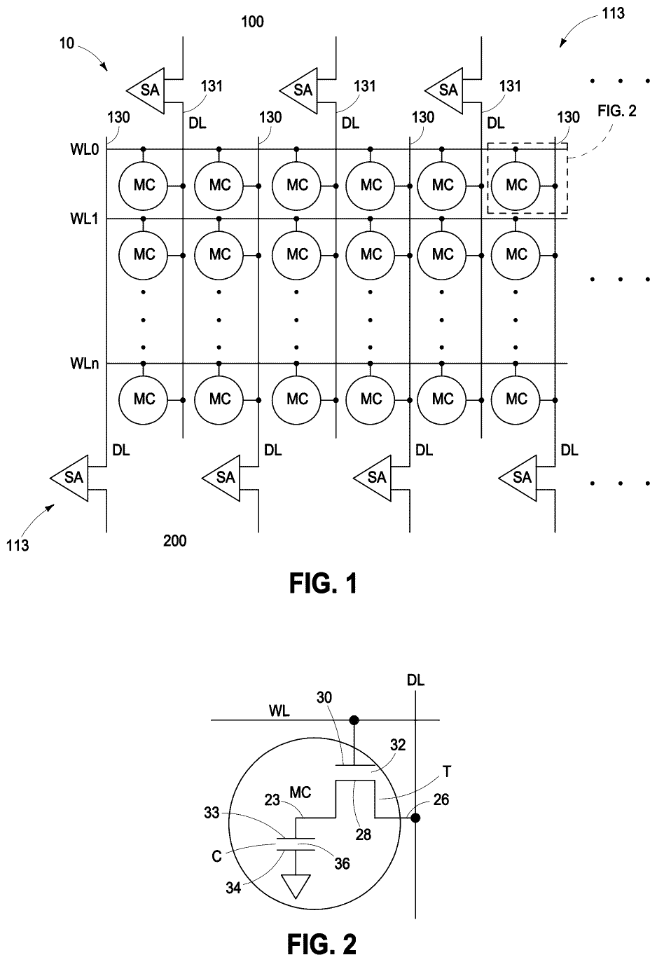

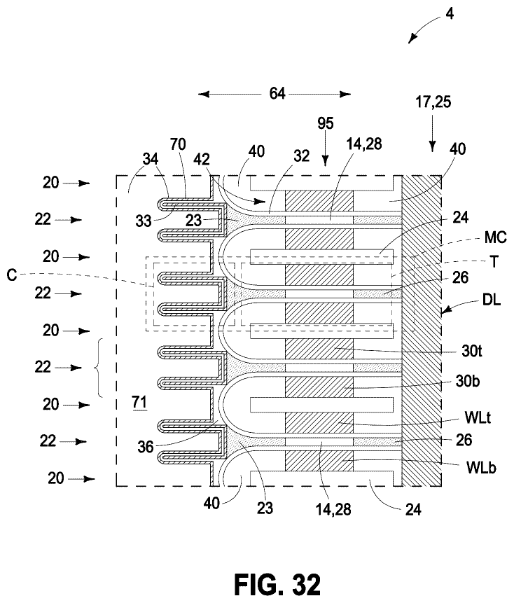

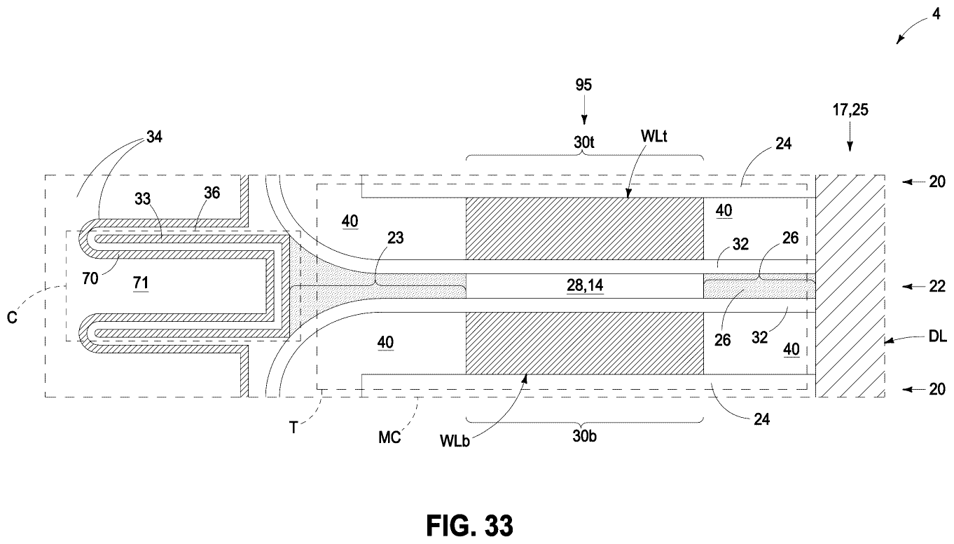

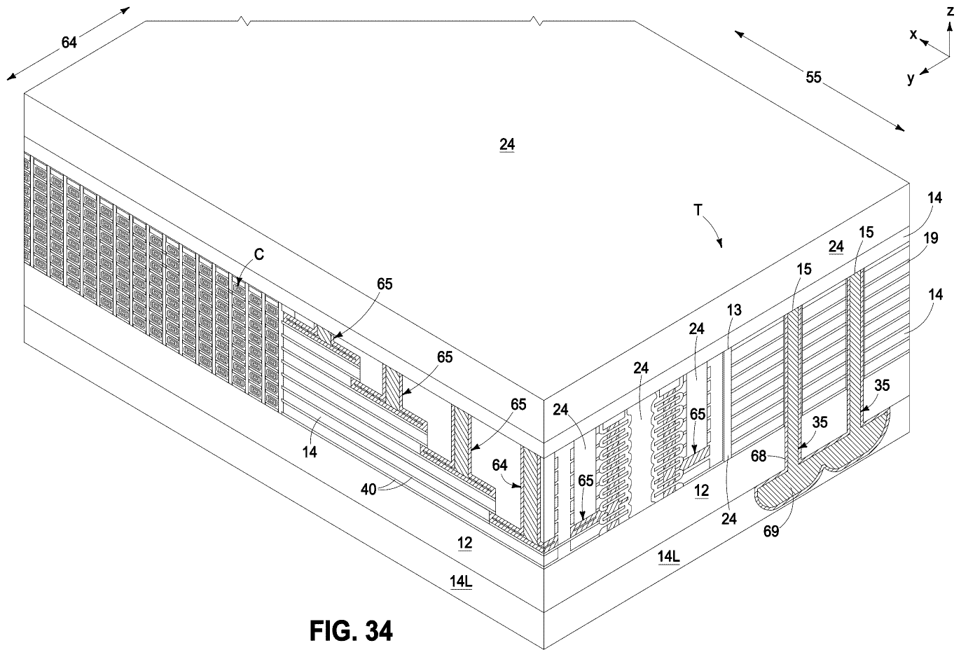

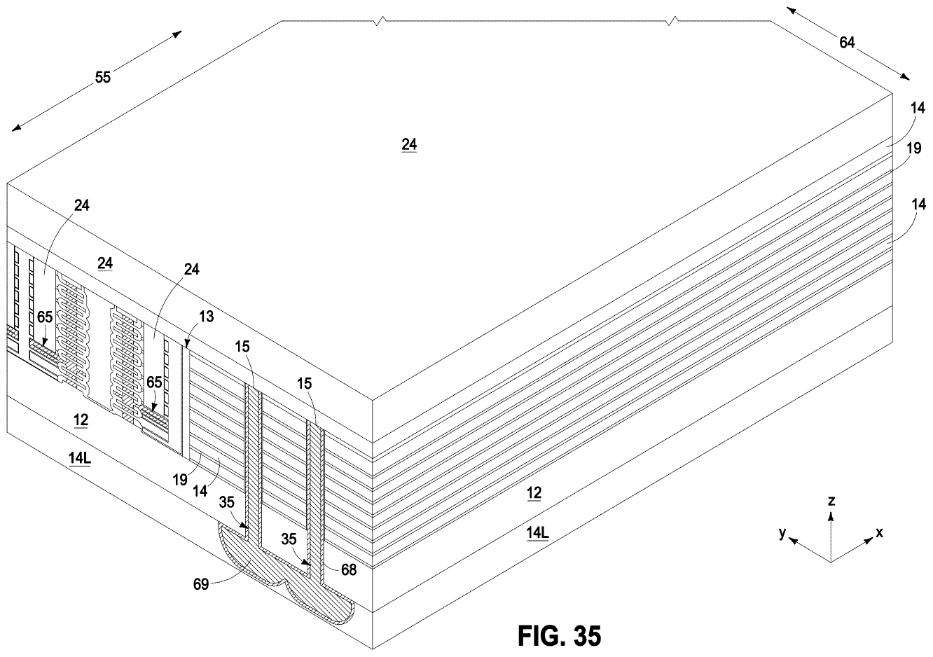

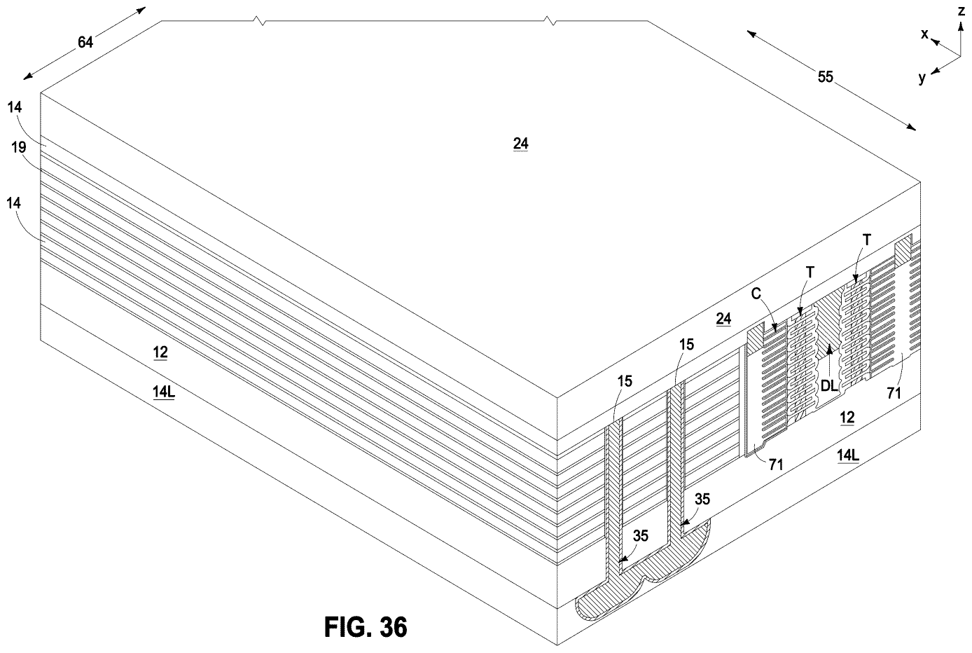

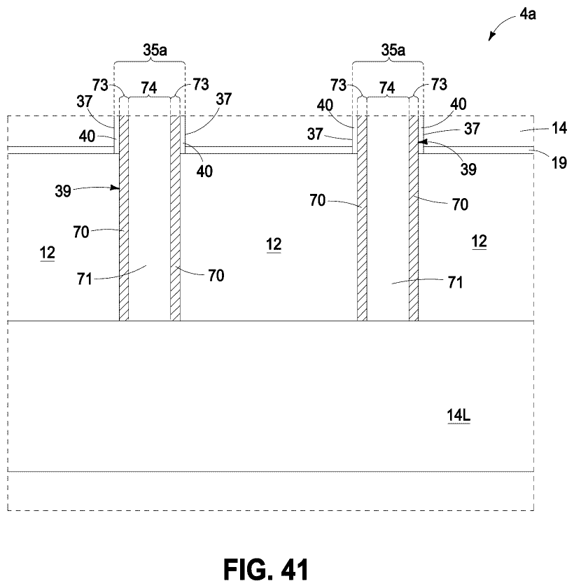

Embodiments of the invention encompass memory circuitry (e.g., DRAM) regardless of orientation (e.g., either horizontal or vertical). In some ideal embodiments, the memory circuitry comprises vertically-alternating insulative tiers and memory-cell tiers, with memory cells in the memory-cell tiers individually comprising a capacitor and a horizontally-oriented transistor. Embodiments of the invention also encompass methods used in forming memory circuitry. Example embodiments are described with reference to FIGS. 1-41.

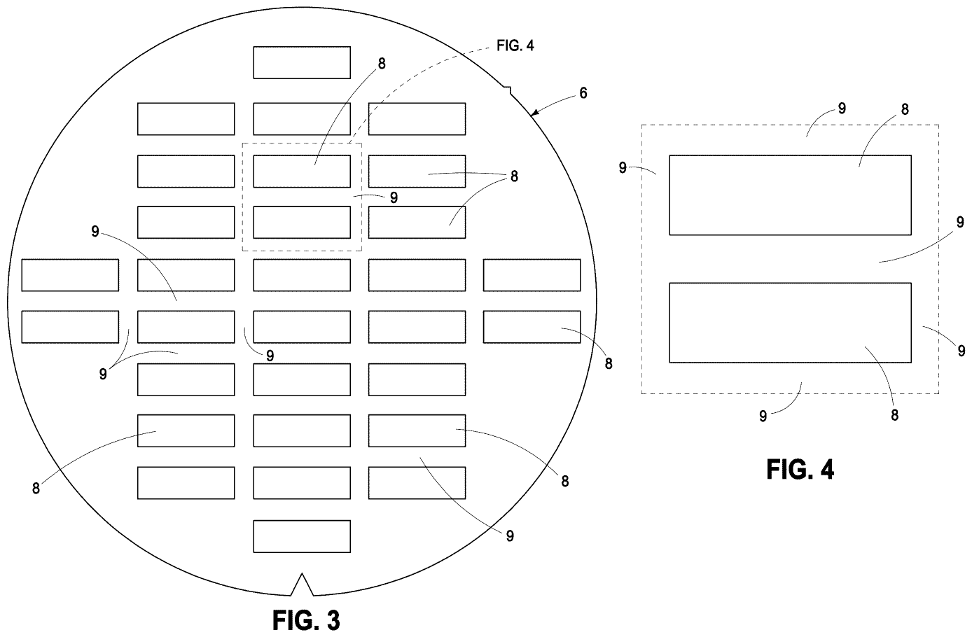

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIG. 3+ have the wordlines/access lines running horizontally and the digitlines/sense lines running vertically.

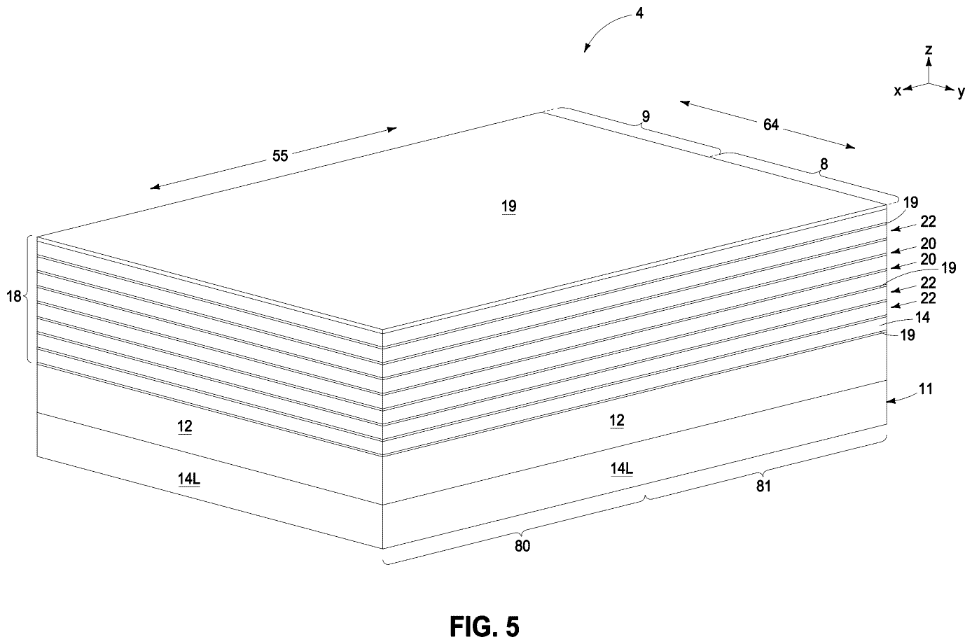

Referring to FIGS. 3-5, an example semiconductor wafer 6 comprises a base substrate 11 and which may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-5-depicted materials. For example, other partially or wholly fabricated components of integrated circuitry may be provided somewhere above, about, or within base substrate 11. For purposes of the continuing discussion, the depicted construction 4 in FIG. 5 may be considered as comprising a first direction 55 (an x direction) and a second direction 64 (a y direction) that are orthogonal relative one another.

Example semiconductor wafer 6 comprises a lower semiconductor material 14L (e.g., lightly-doped or undoped monocrystalline silicon). Semiconductor wafer 6 has been fabricated to have die areas 8 to comprise memory cells (not yet shown) and to have scribe-line area 9 around individual of die areas 8. Die areas 8 and scribe-line area 9 may not be perceptible at this point of processing. Many more die areas 8 (e.g., 100+) would typically be on a single semiconductor wafer 6 and scribe-line area 9 would not be as wide as shown, meaning both die areas 8 and scribe-line areas 9 would be much smaller than shown, but are shown as-is for clarity in the figures.

In some embodiments, die areas 8 will be fabricated to individually comprise a vertical stack of the memory cells, with the memory cells individually comprising a capacitor and a horizontal transistor. In some embodiments, die areas 8 individually comprise a memory-array region 80 and an adjacent region 81 that is horizontally adjacent memory-array region 80, and which may not be perceptible at this point of processing. In the example embodiment, memory-array region 80 and adjacent region 81 are directly against one another (i.e., they are immediately-adjacent one another, with “immediately-adjacent” with respect to regions meaning there is no other region between those that are immediately-adjacent one another). Alternately, a buffer region (not shown) may be between memory-array region 80 and adjacent region 81. In such instance, memory-array region 80 and an adjacent region 81 are still horizontally adjacent one another although not immediately-adjacent one another due to the buffer region.

Scribe-line area 9 comprises lower semiconductor material 14L, an insulative material 12 (e.g., silicon dioxide and/or silicon nitride) directly above (e.g., directly against) lower semiconductor material 14L, and a stack 18 comprising alternating tiers 20, 22 of different composition semiconductive materials 14 and 19 directly above (e.g., directly against) insulative material 12. Only a few tiers 20 and 22 are shown, with the example construction likely comprising many more (e.g., dozens, hundreds, etc.). In one embodiment, one of the different composition semiconductive materials comprises silicon (e.g., 14; e.g., the same composition as lower semiconductor material 14L) and the other (e.g., 19) comprises a silicon-germanium alloy (e.g., Si₁₋ₓGeₓ, and which may include one or more additional elements). In one such embodiment, such silicon 14 is at least twice as thick as silicon-germanium alloy 19. In one embodiment, remnant portions of tiers 22 will comprise memory-cell tiers 22 and tiers 20 will comprise insulative tiers 20 in die areas 8 in the finished circuitry constructions. Die areas 8 and all of semiconductor wafer 6 may be fabricated to comprise materials 14, 12, 14, and 19.

The discussion proceeds with subsequent processing including many steps which are included for completeness, best mode, and/or enablement, but which are not required in aspects of the inventions which are defined only by express limitations in each claim under analysis.

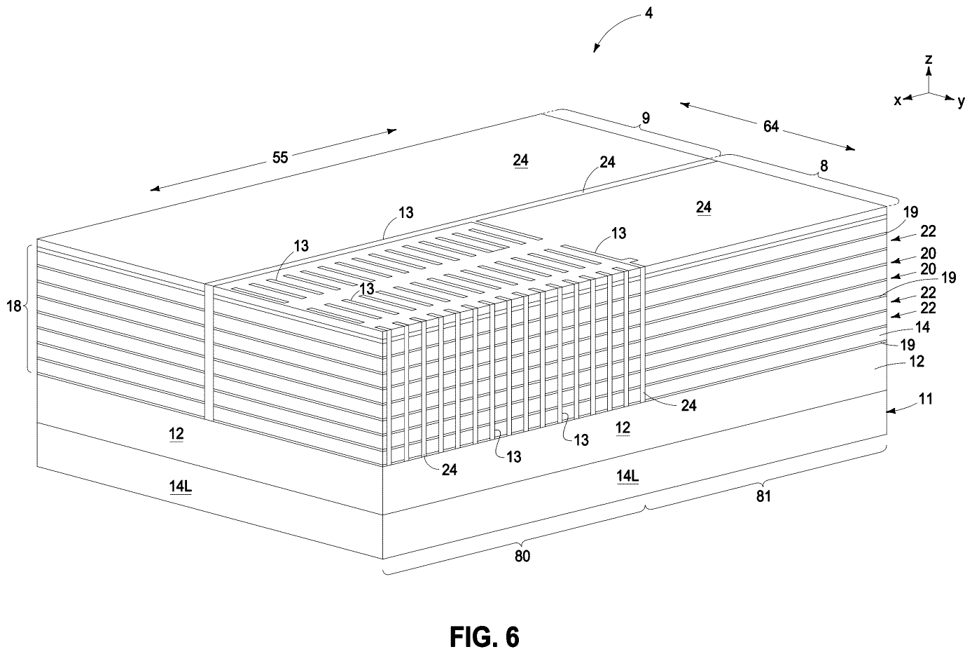

Referring to FIG. 6, insulative material 24 (e.g., silicon dioxide) has been formed atop stack 18, followed by forming isolation trenches 13 and filling such with insulative material 24. Those of trenches 13 that are elongated along second direction 64 may electrically isolate memory cells that are immediately-adjacent one another in first direction 55 in the same memory-cell tier. That trench which is elongated along first direction 55 may be a peripheral isolation trench that encircles within individual die areas 8.

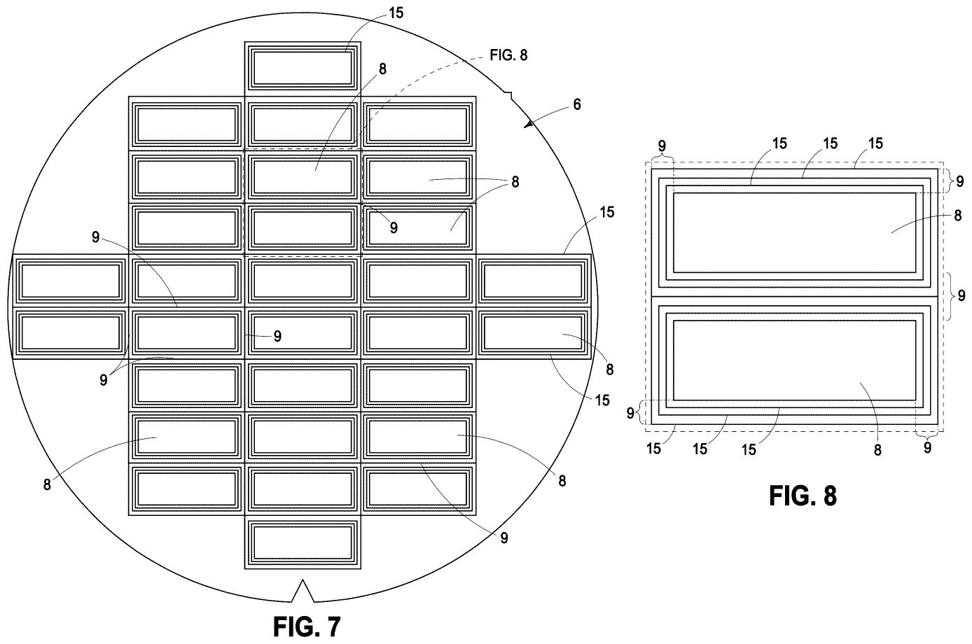

Referring to FIGS. 7-9, a plurality of ring trenches 15 have been formed in scribe-line area 9 and that individually at least partially surround individual die areas 8. In this document, “at least partially surround” requires that at least 50% of the circumference of a die area 8 be surrounded. Preferably, trenches 15 surround much more than 50% of the die circumference, including completely surrounding such (i.e., 100%). Ring trenches 15 are indicated with a single line in FIGS. 7 and 8 due to scale. In some embodiments, ring trenches 15 are referred to as trenches 15 without the adjective “ring” or as initially-formed trenches 15. Trenches 15 in one embodiment extend through stack 18 and insulative material 12 to lower semiconductor material 14L (not yet shown). In one such embodiment and as shown, such trenches 15 are initially formed to stop atop or in insulative material 12 (atop being shown). Regardless and in one embodiment as shown, more than one trench 15 is formed around individual die areas 8. Likely more trenches 15 would be formed in scribe-line area 9 around individual die areas 8, but such are not shown, again due to scale and for clarity.

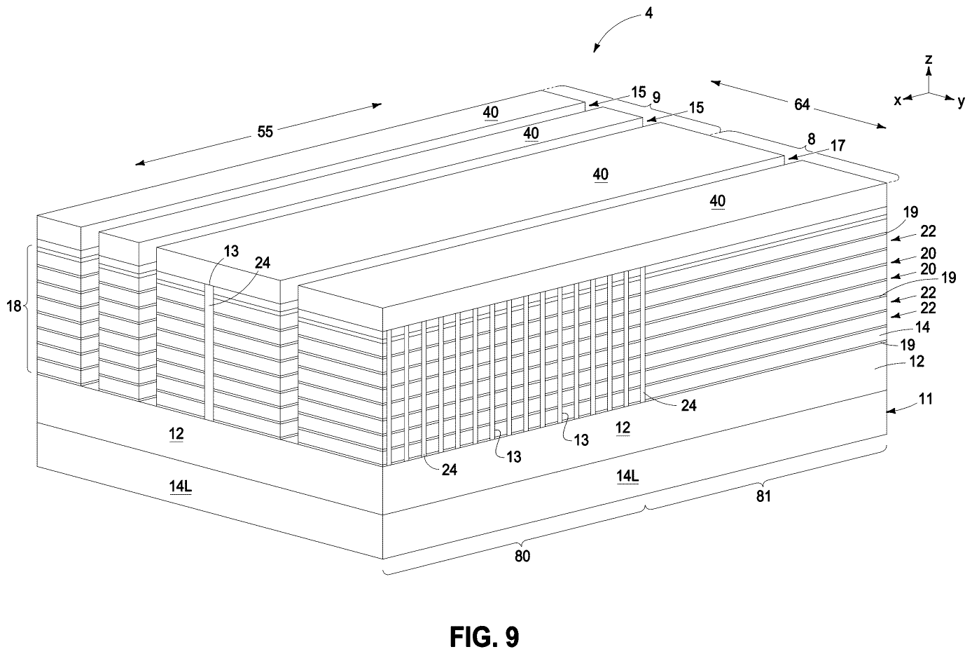

A plurality of digitline trenches 17 (only one being shown) have also been formed in die areas 8 (e.g., in memory-array region 80 and in adjacent region 81). In this document, a digitline trench is a horizontally-elongated trench (e.g., elongated in direction 55) in which a digitline has been or will be formed. Digitline trenches are not shown in die areas 8 in FIGS. 7 and 8 due to scale. In one embodiment, ring trenches 15 in scribe-line area 9 and digitline trenches 17 in individual die areas 8 are simultaneously formed in a single masking step. By way of example, FIG. 9 shows a hard-mask material 40 (e.g., silicon nitride) having been formed atop stack 18 before forming trenches 15 and 17. A masking material (e.g., photoresist and not shown) may have been atop such hard-mask material 40 and openings formed there-through having positions and outlines corresponding to those of trenches 15 and 17. Such has been used to etch trenches 15 and 17 through hard-mask material 40, followed by etching through stack 18 and ultimate removal of the masking material, thus constituting a single mask step in forming trenches 15 and 17.

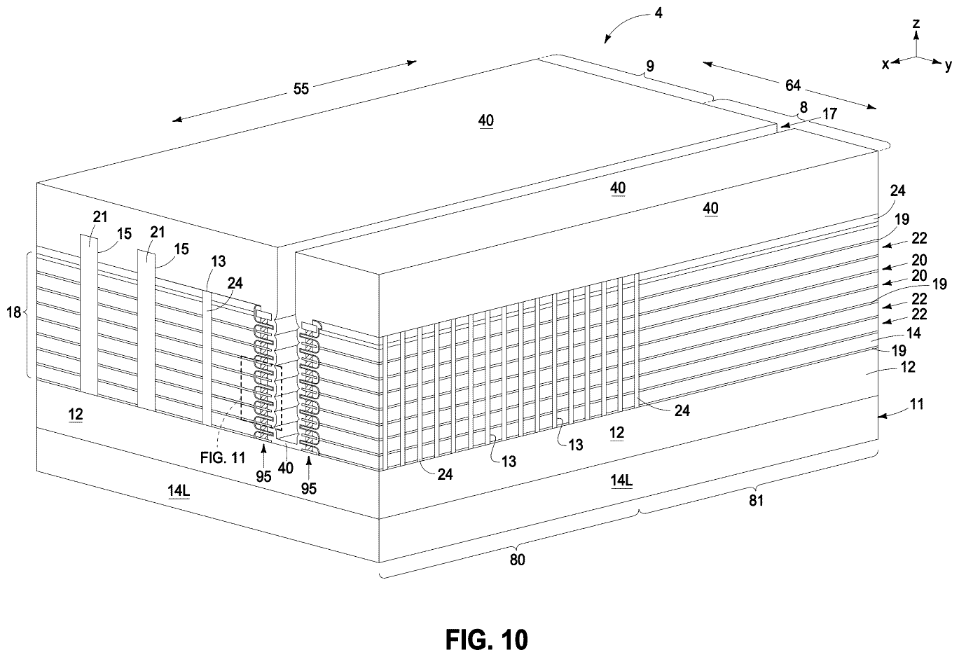

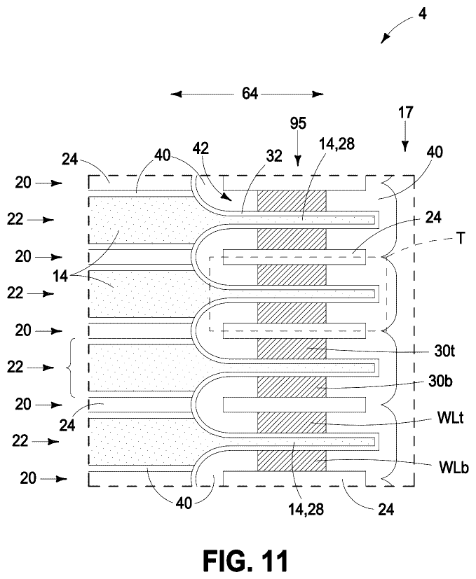

Referring to FIGS. 10 and 11, several processing steps have occurred. First, trenches 15 and 17 were occluded (e.g., filled as shown) with temporary material 21 (e.g., carbon). Second, another layer of insulative material (e.g., silicon dioxide and not shown) was formed and trenches (not shown) formed there-through to expose digitline trenches 17 while keeping trenches 15 masked with such insulative material. Third, temporary material 21 was removed from digitline trenches 17 (no longer there-shown). Then, several more processing steps occurred in at least partial formation of horizontal transistors T in memory-cell tiers 22 that alternate with insulative tiers 20 (e.g., comprising insulative material 24) in memory-array region 80. Memory cells (e.g., MC, and not-yet-completed and not yet-so-designated) in memory-cell tiers 22 will comprise horizontal transistor T comprising a gate 30* (an * being used as a suffix to be inclusive of all such same-numerically-designated structures or portions thereof that may or may not have other suffixes) and a channel material 14/28 that is operatively-proximate gate 30* (a gate insulator 32 being there-between). Channel material 14/28 comprises semiconductor material and portions of which will comprise conductively-doped source/drain-region material of the horizontal transistors T being formed as is described below. Channel material 14/28 is in part indicated with the same numeral as material 14 of base substrate 11 although different semiconductor composition(s) therefrom may be used.

Gate 30* comprises part of one of a plurality of horizontal conductive access lines WL* that individually directly electrically couple together multiple of gates 30* of different ones of the horizontal transistors that are (will be) in the same memory-cell tier 22. In one embodiment and as shown, individual of access lines WL* comprise a top access line WLt and a bottom access line WLb, with gate 30* comprising a top gate 30t that is part of top access line WLt and comprising a bottom gate 30b that is part of bottom access line WLb. Access lines WL* in different ones of memory-cell tiers 22 are in a vertical stack 95. Example access lines WL* in different ones of memory-cell tiers 22 in vertical stack 95 laterally overlap one another in second direction 64. By way of example only, access lines WL* are shown as having perfectly laterally-coincident second-direction edges and the same second-direction widths relative one another. Regardless, access lines WL*, vertical stack 95, and channel material 14/28 extend horizontally along first direction 55 from memory-array region 80 into adjacent region 81 (not apparent in FIG. 10 but will be apparent in subsequent figures). As shown, channel material 14/28 extends laterally-beyond a same one lateral side 42 of top and bottom access lines WLt and WLb in second direction 64 in each stack 95. As stated above, a buffer region (not shown) may be between adjacent region 81 and memory-array region 80 (e.g., where no operative memory cells would be formed). Another buffer region (not shown) and another adjacent region 81 (not shown) may be on the opposite first-direction side of depicted memory-array region 80 (downwardly to the left in FIG. 10). Regardless, the example construction is shown as having been formed to also comprise additional insulative material 24, insulating material 40 (e.g., silicon nitride), and gate insulator 32 (e.g., silicon dioxide, hafnium oxide, silicon nitride, etc.).

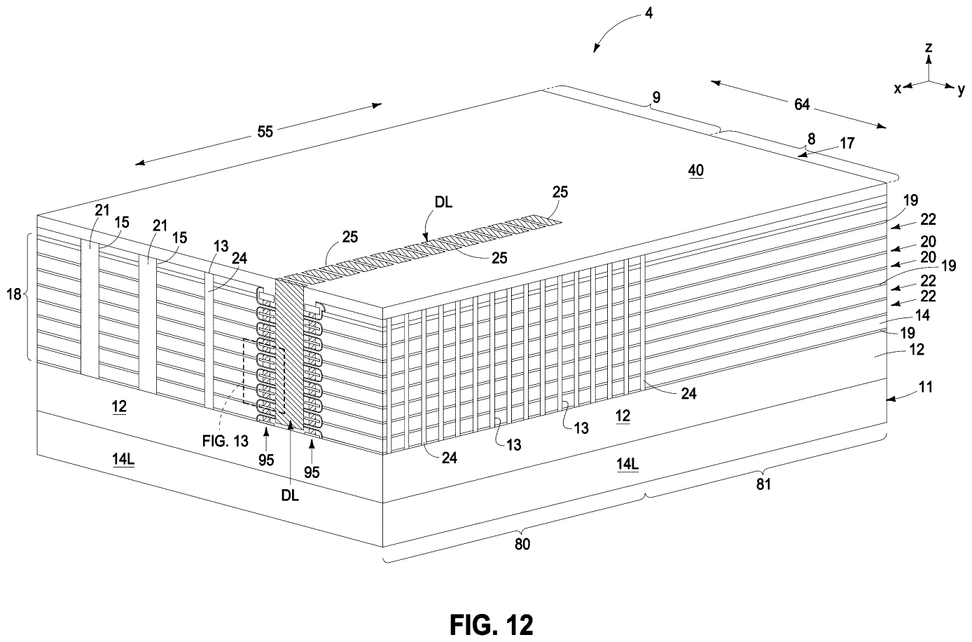

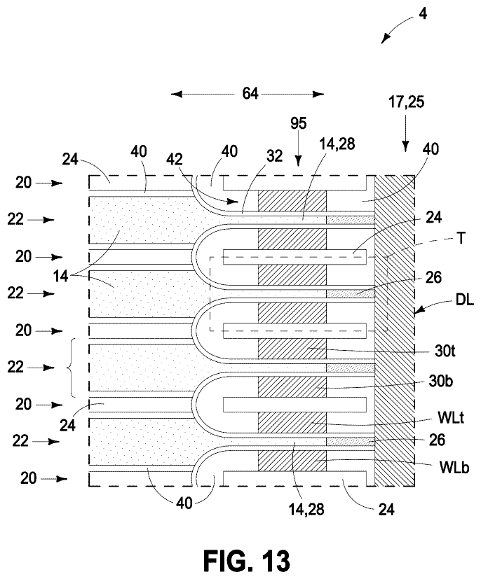

Referring to FIGS. 12 and 13, several processing steps have occurred. Remaining volume of digitline trenches 17 was filled with insulative fill material (e.g., silicon dioxide and not shown). Then, the former hard-mask material (e.g., 40) was removed (no longer shown) to expose the uppermost layer of insulative material 24. Then, the uppermost access line WL* was removed. This was followed by formation of more hard-mask material 40. Such was thereafter patterned to form openings 25 through hard-mask material 40 and the insulative fill material there-below, with openings 25 individually being between the insulator-filled trenches 13 that are horizontally elongated in second direction 64 and spaced along first direction 55 (not visible in FIGS. 12 and 13; see FIG. 6). Insulating material 40 that was within openings 25 (e.g., as shown in FIGS. 10 and 11) and side portions of gate insulator 32 were removed to expose semiconductor material 14 of memory-cell tiers 22. The latter was then conductively doped through openings 25 (e.g., by gas phase diffusion) to form a conductively-doped source/drain regions 26 of the horizontal transistors of the memory cells being formed. Alternately, semiconductor material 14 of memory-cell tiers 22 may be exposed and such conductively-doping occur before forming the insulative fill material in digitline trenches 17. Regardless, after forming conductively-doped source/drain regions 26, digitlines DL have been formed in openings 25 and thereby within digitline trenches 17. Alternate methods may of course be used to form digitlines DL in digitline trenches 17 (e.g., which are now individually filled with digitlines DL and insulative material 24 in trenches 13 as was shown in FIG. 6).

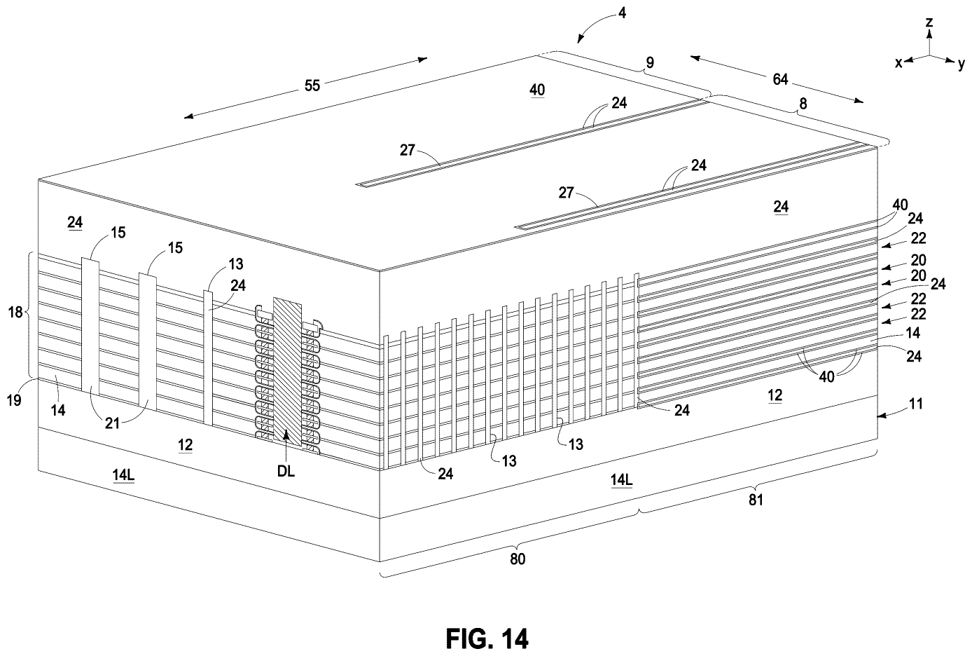

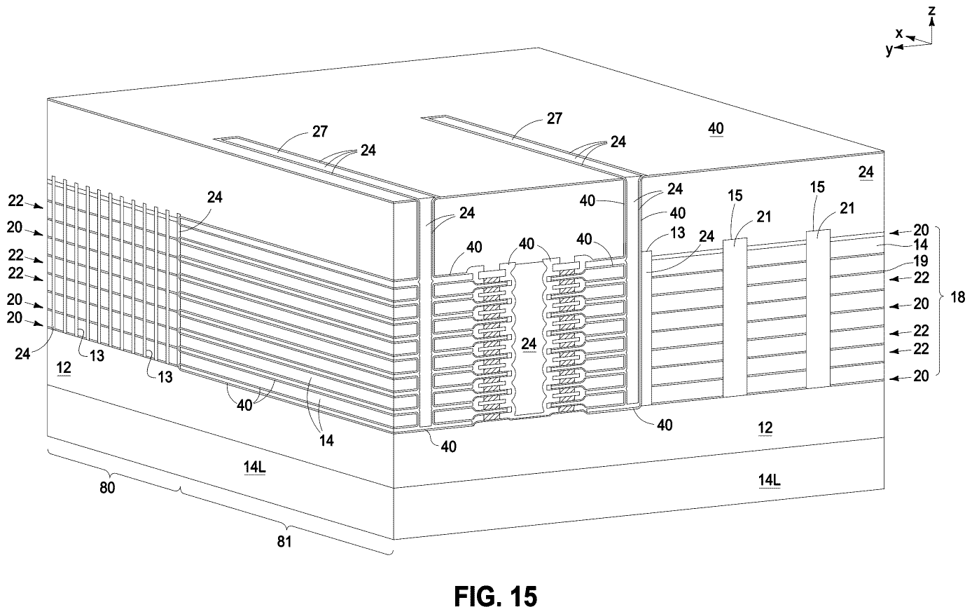

Referring to FIGS. 14 and 15, several processing steps have occurred. Hardmask/Insulating material 40 was removed followed by forming insulative material 24 atop stack 18. Then, isolation trenches 27 were formed in adjacent region 81. Then, semiconductive material 19 was recessed (e.g., by etching) in tiers 20. Semiconductive material 14 in tiers 22 may also be removed while and/or after recessing semiconductive material 19, thereby vertically enlarging tiers 20. Thereafter, insulating material 40 and insulative material 24 were formed to fill remaining volume of tiers 20 and isolation trenches 27. More insulating material 40 was then formed atop the construction.

Adjacent region 81 may be fabricated to comprise trench-like cavities that are laterally spaced in the first and second directions and in which staircase structures are fabricated, for example to have opposing flights of stairs in a stadium-like structure or only a single flight of stairs. Different trench-like cavities may extend to different depths within stack 18 where the staircase structures are fabricated. Regardless, individual stairs may comprise a tread and a riser comprising one of the memory-cell tiers for making separate electrical connection with the access lines that are in different memory-cell tiers. If so, such may be fabricated, for example, after the processing shown by FIGS. 1-15 and as is described below. Alternately, no such staircase structures may be fabricated (e.g., a “staircase-less” structure).

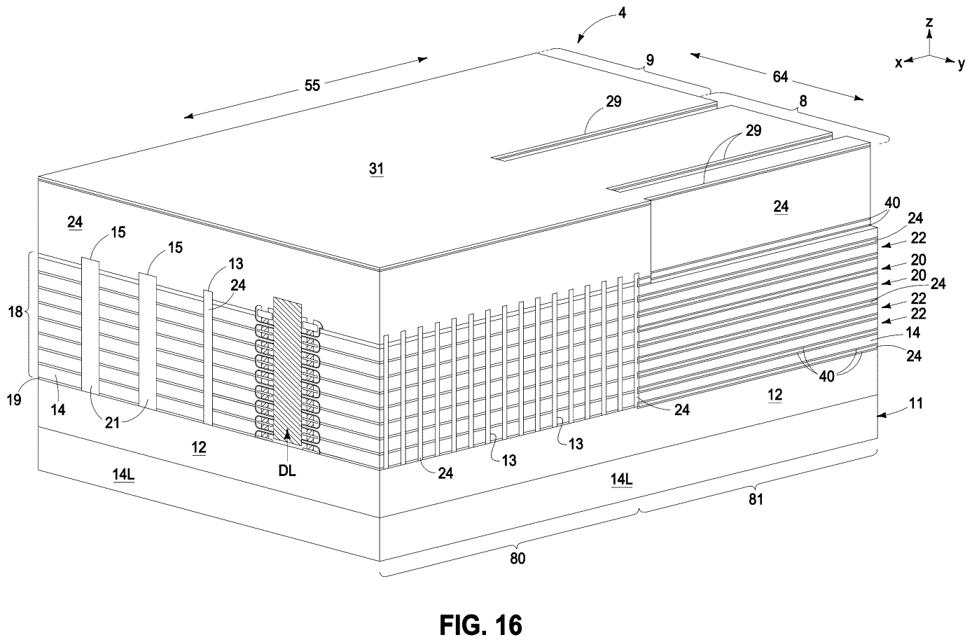

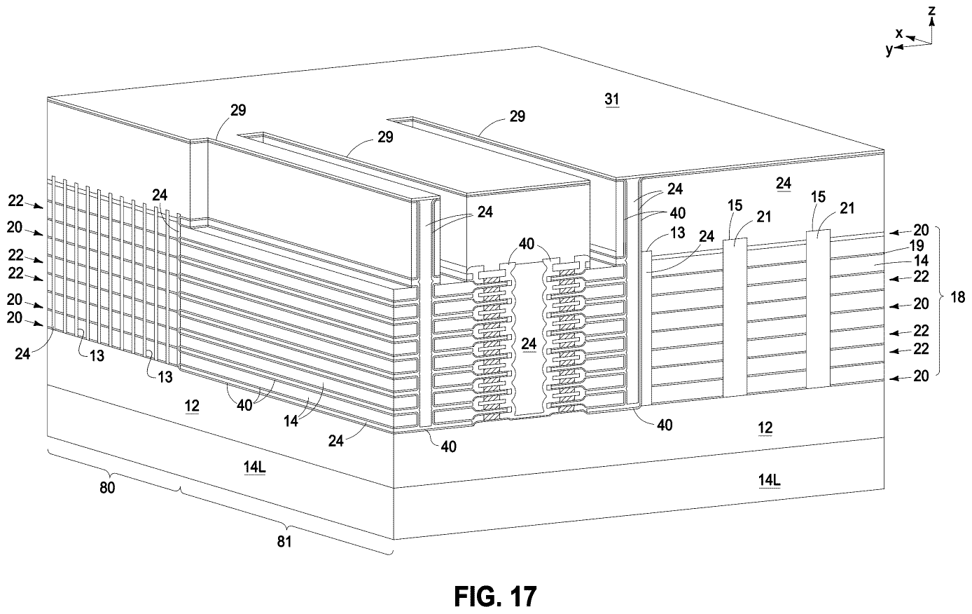

Referring to FIGS. 16 and 17, trenches 29 (e.g., staircase cavities) have been formed in adjacent region 81 through hard-mask/insulative material 24 and to semiconductor material 14. A hard-mask material 31 (e.g., polysilicon) may be formed atop construction 4 prior to forming trenches 29.

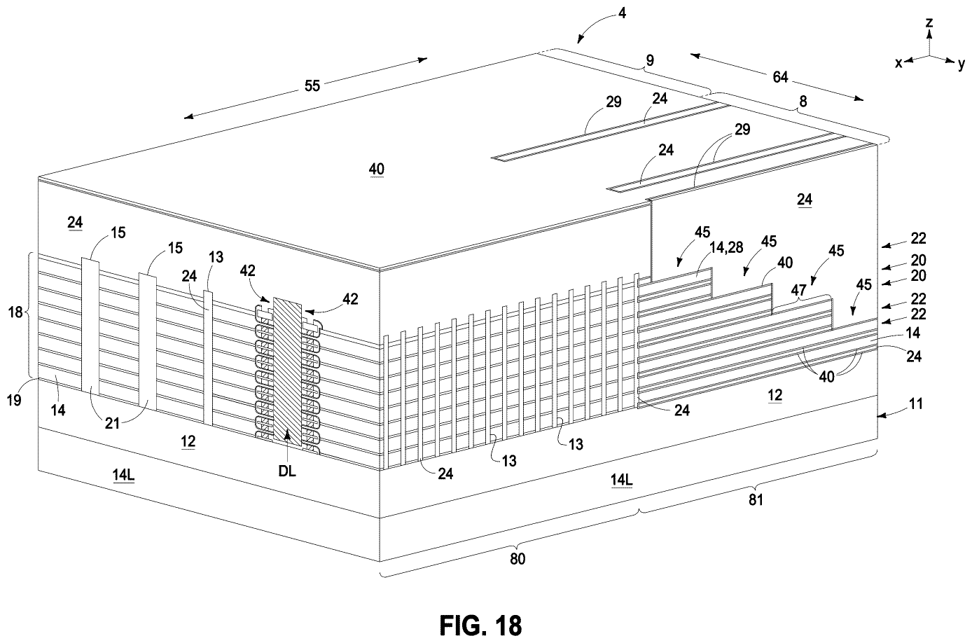

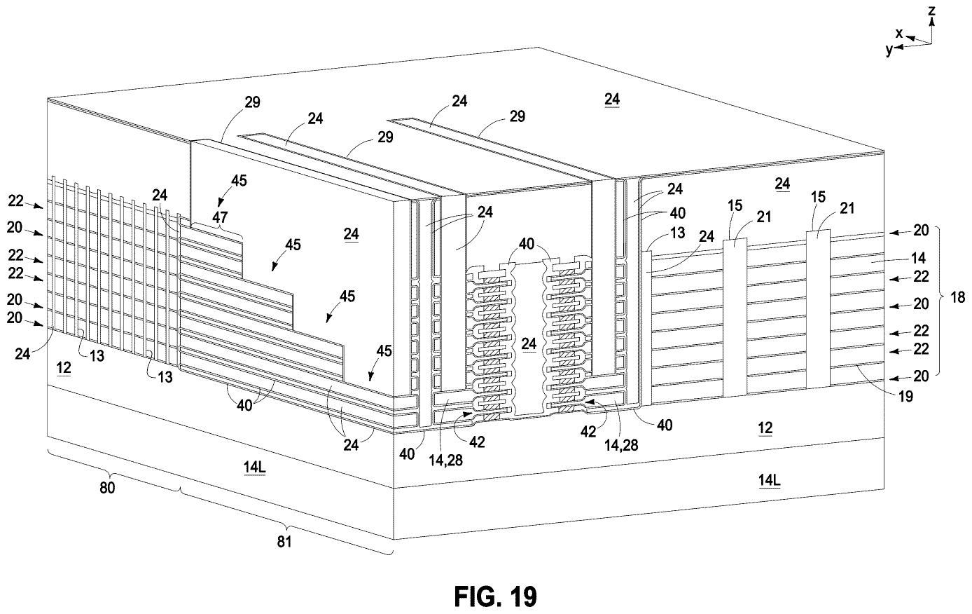

Referring to FIGS. 18 and 19, several processing steps have occurred. First, through trenches 29, stairs 45 were formed in adjacent region 81 (e.g., adjacent region and 81 comprising a stair-step region 81 in the depicted embodiment). Example stairs 45 comprise treads 47 that comprise channel material 14/28 that extends laterally-beyond one lateral side 42. Memory-cell tiers 22 may be considered as comprising consecutively-numbered memory-cell tiers from top to bottom, thereby including odd-numbered memory-cell tiers and even-numbered memory-cell tiers. In one embodiment and as shown, the collective patterning to form stairs 45 in trenches 29 has the top of each tread 47 as comprising channel material 14/28 of only odd-numbered or even-numbered memory-cell tiers in adjacent region 81. A corresponding set of stairs (not shown) would be formed on the opposite side of memory-array region 80 (downwardly to the left in FIG. 18) and which would have the top tier of each tread 47 be the other of odd or even.

By way of example only, stairs 45 may be formed by patterning a hardmask in trenches 29 to have openings there-though to the top layer of channel material 14/28 where the stairs are to be collectively formed on the depicted side of memory-array region 80 or on the opposite side. Then, etching could be conducted through one layer of silicon material 14 and one layer of silicon-germanium material 19 on the depicted side of memory-array region 80 or on the opposite side. The fill-material would then be removed, and a photoresist layer deposited and patterned with an upper opening there-through to each of the lower openings for forming the first/lowest stair in each stair-step region 81. Conventional etch/photoresist-trim/etch/photoresist-trim, etc., two layers of materials 19, 14 at a time, was then conducted to form the illustrated stairs 45. A thin layer of insulating material 40 has then been formed to line trenches 29, followed by filling remaining volume of trenches 29 with insulative material 24.

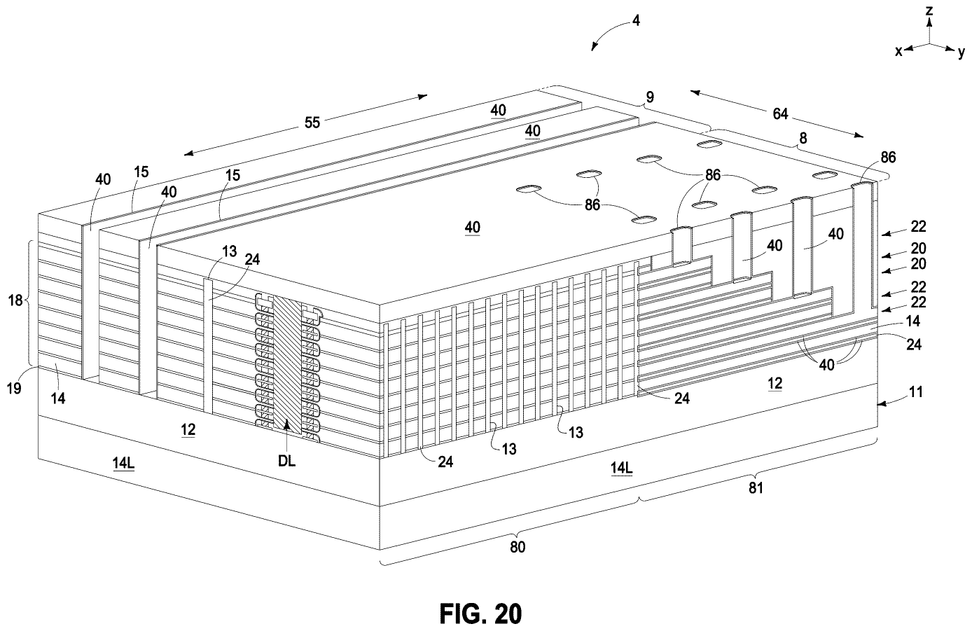

Referring to FIG. 20, several processing steps have occurred. Hard-mask/Insulative material 24 was polished back to expose temporary material 21 (no longer shown) that was in ring trenches 15. Then, more hard-mask material 40, carbon (not shown), and a masking layer (e.g., photoresist and not shown) was formed atop the construction. Then, the masking layer and hard-mask material 40 were patterned to form ring trenches 15 in the masking layer and hard-mask material 40 to expose temporary material 21 (no longer shown) that was in ring trenches 15 that are in stack 18 (as is shown with respect to added hard-mask material 40). Thereafter, temporary material 21 (no longer shown) was removed from ring trenches 15 that are in stack 18. Additionally, conductive-via openings 86 were formed in adjacent region 81 and that individually extend to have a bottom that is in one of memory-cell tiers 22 comprising one of access lines WL*. In this document, a “conductive-via opening” is an opening in which a conductive-via construction has been or will be formed. The carbon layer (never shown) was then removed and insulating material 40 was formed in initially-formed trenches 15 and conductive-via openings 86 to line sidewalls of and less-than-fill such trenches and openings. Such insulating material 40 was then punch-etched to expose insulative material 12 at the bottoms of initially-formed trenches 15 and semiconductive material 14 at the bottoms of conductive-via openings 86. In one embodiment and as shown, digitlines DL have been formed in digitline trenches 17 before the lining of the sidewalls of ring trenches 15 with insulating material 40.

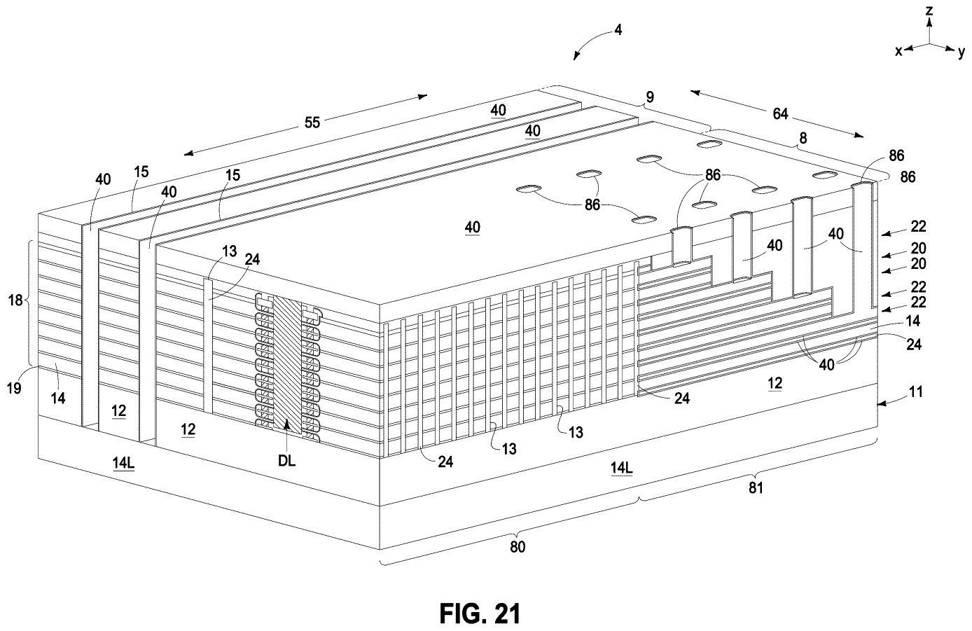

Referring to FIG. 21, within the initially-formed trenches 15, etching has been conducted through insulative material 12 to lower semiconductor material 14L.

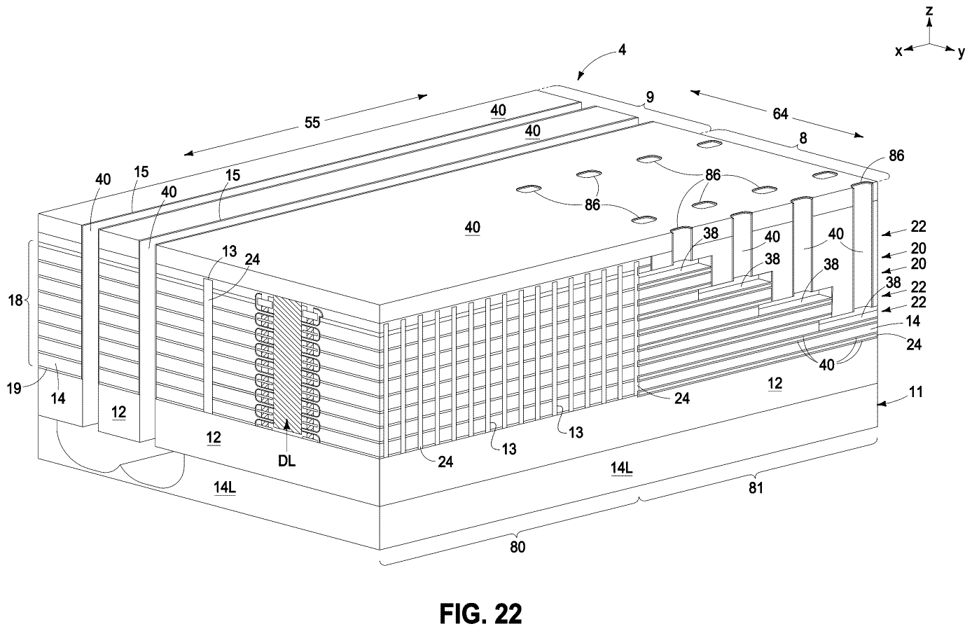

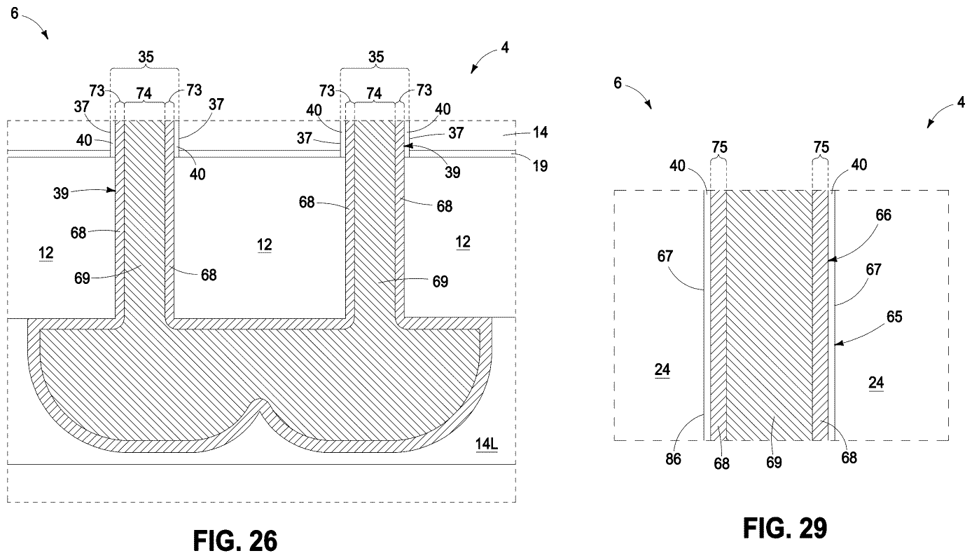

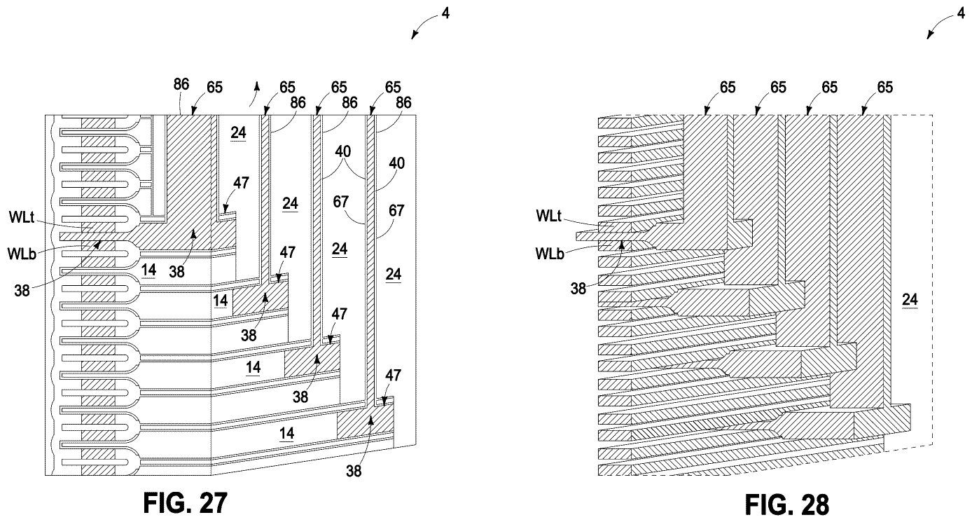

Referring to FIG. 22 and in one embodiment and as shown, etching has also been conducted into lower semiconductor material 14L through trenches 15 after etching through insulative material 12. Such may be an artifact of processing associated with respect to conductive-via openings 86. Specifically, and nevertheless, etching of some of semiconductive material 14 has occurred in individual tiers 22 through conductive-via openings 86 (which also has etched into lower semiconductor material 14L through trenches 15). Such etching through conductive-via openings 86 has been sufficient to remove at least some of semiconductive material 14 from being vertically between access lines WLt and WLb in individual tiers 22, thus creating a void space 38 a portion of which is vertically between WLt and WLb (“vertically between” not visible in FIG. 20 but is visible in FIGS. 27 and 28 which are referred to below).

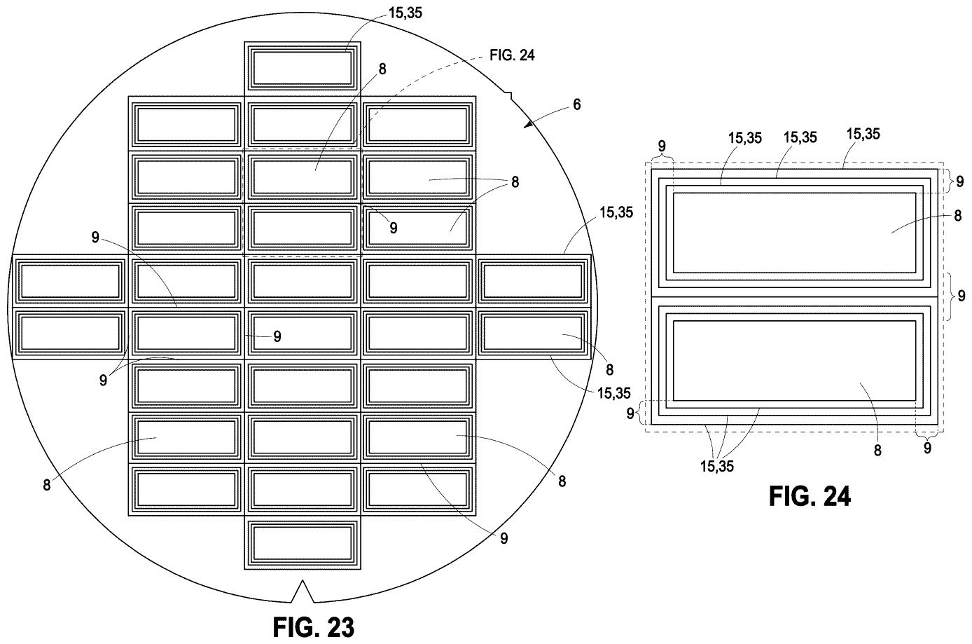

Referring to FIGS. 23-29, several processing steps have occurred. First, a conductive-wall construction 35 has been formed in individual ring trenches 15 and that at least partially surrounds one of individual die areas 8 (e.g., completely surrounds such as shown). In one embodiment and as shown, more than one such conductive wall-construction 35 has been formed around individual die areas 8. Regardless, conductive-wall construction 35 extends through a majority of thickness of semiconductor wafer 6 and in one embodiment as shown extends through stack 18 and insulative material 12 to lower semiconductor material 14L. Conductive-wall construction 35 comprises two laterally-outer regions 37 of insulating material 40 (e.g., silicon nitride and/or silicon dioxide) having a conductive core 39 laterally there-between. Conductive core 39 is directly electrically coupled to lower semiconductor material 14L (e.g., is directly there-against). In one embodiment and as shown, two laterally-outer regions 37 of the insulating material terminate above or in insulative material 12 (above as shown).

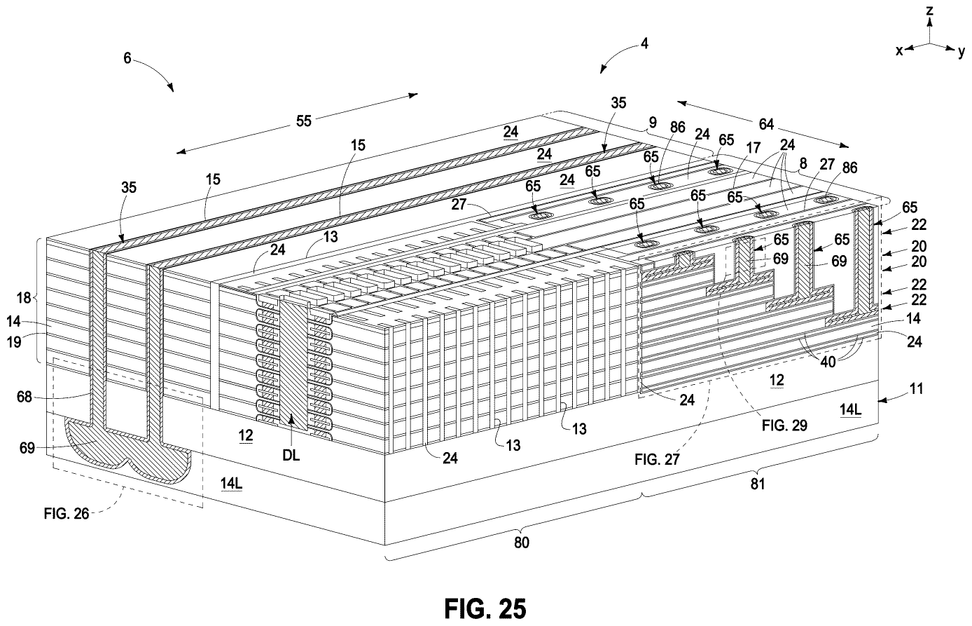

Second, a conductive-via construction 65 has been formed in individual of conductive-via openings 86. Such comprises a conductive core 66 and a radially-outer insulative lining 67 circumferentially there-about (e.g., comprising insulating material 40). Conductive core 66 directly electrically couples with the one access line WL* in the one memory cell tier to which the individual conductive-via opening 86 extends. In one embodiment, individual conductive-via openings 86 and conductive-via construction 65 therein are laterally aside (at least in part) the one access line WL*. FIGS. 27 and 28 are provided for clarity, are very diagrammatic, and don't show the exact structure as shown in FIG. 25. In FIG. 28, all insulative material has been removed with only conductive material being shown for clarity.

In one embodiment, conductive-wall construction 35 and conductive-via construction 65 are formed at the same time (i.e., simultaneously). Regardless, in one embodiment, conductive cores 39 and 66 comprise first and second conductive materials 68, 69 that are of different compositions relative one another. In one such embodiment, in conductive-wall construction 35, first conductive material 68 is in two laterally-outer regions 73 that are laterally outward of a laterally-inner region 74 of second conductive material 69, and in conductive-via construction 65, first conductive material 68 is in a radially-outer region 75 that is directly against radially-outer insulative lining 67 and is radially outward of second conductive material 69. In one embodiment, first conductive material 68 is titanium nitride and second conductive material 69 is elemental tungsten.

Third, hard-masking material 40 that was formed in FIG. 20 has been removed and is accordingly no longer shown.

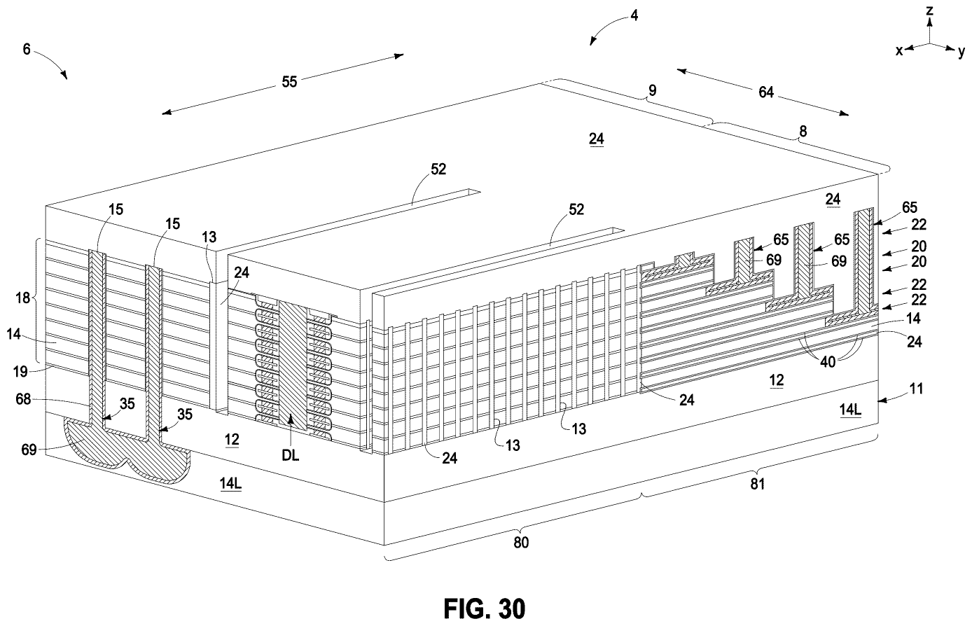

Referring to FIG. 30, more insulative/hard-mask material 24 has been formed, followed by forming capacitor trenches 52 in individual die areas 8. In this document, a “capacitor trench” is a horizontally-elongated trench (e.g., elongated in direction 55) in which a capacitor has been or will be formed.

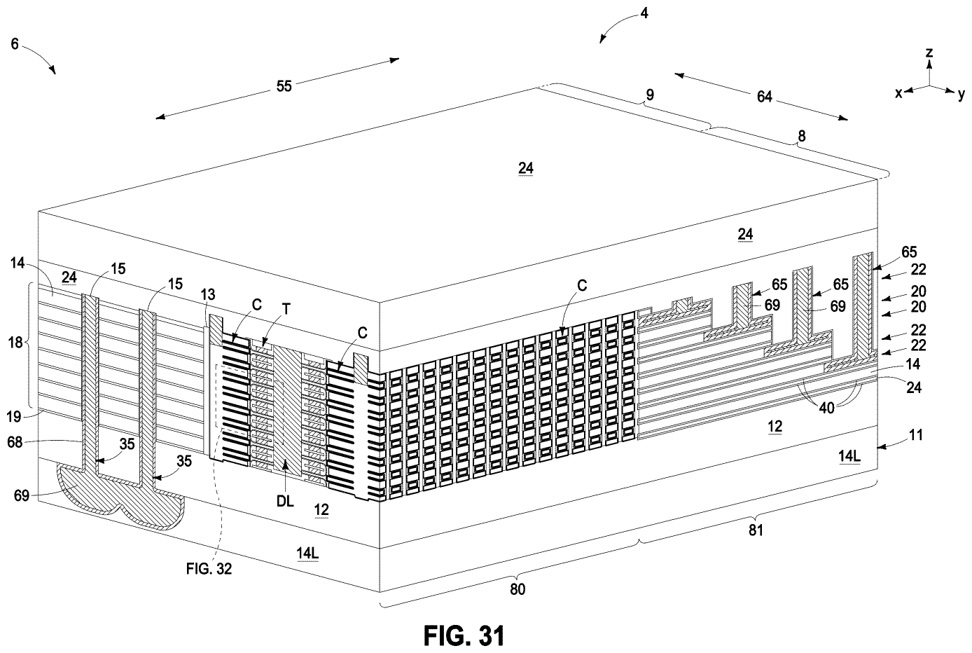

Referring to FIGS. 31-36, subsequent processing has occurred in memory-array region 80 to form a vertical stack of memory cells MC to individually comprise a horizontal transistor T and a capacitor C, and which are in individual die areas 8. For example, some semiconductive material 14 was removed in individual tiers 22 through capacitor trenches 52 and some remaining semiconductive material 14 was conductively doped (e.g., by gas phase diffusion) to form a source/drain region 23 of individual horizontal transistors T. Capacitors C were then formed to individually be electrically coupled with individual horizontal transistors T. Then, more insulative material 24 was formed atop construction 4.

Individual horizontal transistors T comprise first source/drain region 23, second source/drain region 26, and a channel material/region 28, 14 horizontally between first and second source/drain regions 23 and 26. Regions 23, 26, and 28 of different immediately-horizontally-adjacent memory cells MC along direction x are isolated relative one another by insulative material 24 in trenches 13 (not visible in FIG. 31-36, but visible in earlier figures). Horizontal transistors T also individually comprise gate 30* (e.g., gate-all-around the channel) having gate insulator 32 (e.g., dielectric or ferroelectric) between at least channel region 28 and gate 30*.

Example capacitors C were formed in capacitor trenches 52 and individually comprise a conductive first capacitor electrode 33 (e.g., a conductive storage-node electrode), a conductive second capacitor electrode/cell plate 34 (e.g., comprising conductive metal material 70 and conductively-doped semiconductive material such as a boron-doped silicon-germanium alloy 71), and a capacitor insulator 36 there-between (e.g., comprising insulating material that is dielectric or ferroelectric). Example second capacitor electrodes 34 of multiple capacitors C are directly electrically coupled with one another. Example first capacitor electrode 33 is directly coupled to first source/drain region 23 of horizontal transistor T. Individual second source/drain regions 26 of individual transistors T that are in different memory-cell tiers 22 are directly electrically coupled to individual digitlines DL, thereby directly electrically coupling memory cells MC with digitlines DL.

All of the above collective processing is but one example sequence in forming the various described and illustrated electronic components. Yet, capacitors C, digitlines DL, conductive-via construction 65, and/or conductive-wall construction 35 may be formed in any order relative one another in other embodiments, for example as is described in some embodiments below.

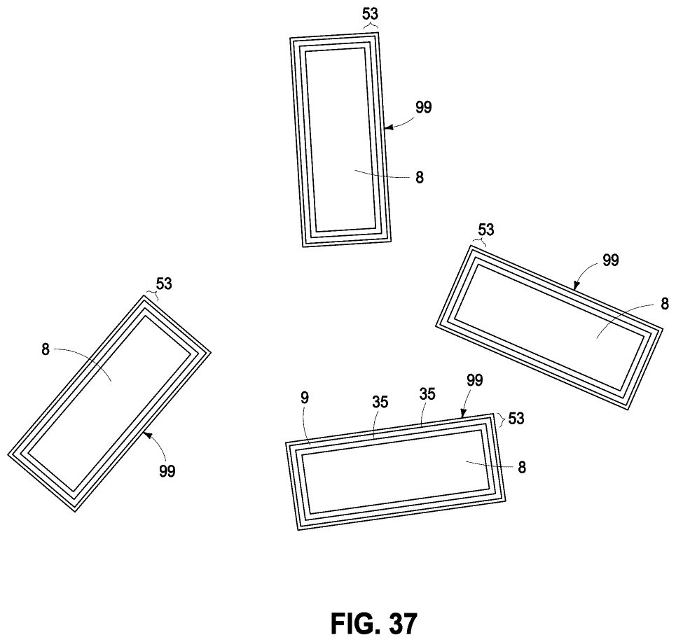

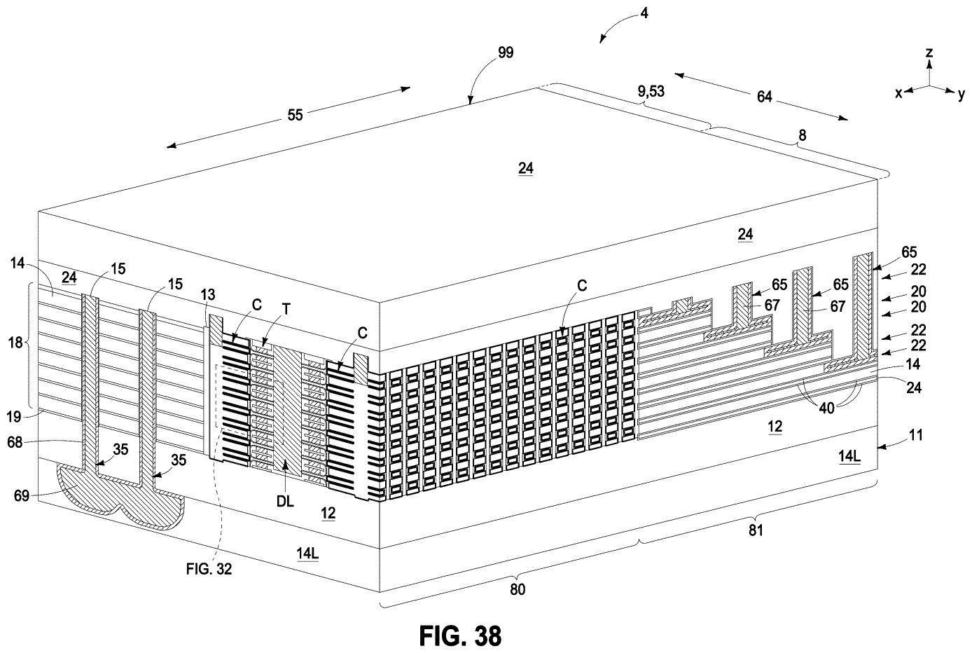

Referring to FIGS. 37 and 38, and in one embodiment, scribe-line area 9 of semiconductor wafer 6 (whole wafer 6 no longer being in existence and thereby not shown) has been diced through (singulated) to form individual die 99 therefrom (four being shown) that comprise one of die areas 8. FIGS. 37 and 38 are intended to show singulation of wafer 6 into die 99, yet with such die 99 as depicted in FIG. 38 being diagrammatic only as more connections and structure would exist in a finished construction and which are not there-shown (e.g., conductive connections to conductive-via constructions 65, control circuitry above and/or below construction 4 for example part of another wafer containing such control circuitry that was bonded to construction 4/wafer 6 prior to singulation, etc.). Individual die 99 comprise a radially-outermost region 53 surrounding the one die area 8 and that comprises part of scribe-line area 9 of the former semiconductor wafer 6. Conductive-wall construction 35 remains in radially-outermost region 53 after the dicing. In one embodiment where more than one conductive-wall construction 35 is formed around individual die areas 8, at least two of conductive-wall constructions 35 remain in radially-outermost region 53 after the dicing, for example the two depicted conductive-wall constructions 35. In one such embodiment and as shown, conductive cores 39 of such at least two conductive-wall constructions 35 are directly against one another in lower semiconductor material 14L.

Any other attribute(s) or aspect(s) as shown and/or described herein with respect to other embodiments may be used.

The above-described processings are but examples and in one example sequence of forming the various components of the example memory circuitry. Other sequences may of course be used, for example forming the capacitors before forming the digitlines and/or before forming the access lines. Further, and regardless, in one example in the above-described embodiments, digitline trenches 17 and ring trenches 15 were formed simultaneously in a single masking step. Alternately or additionally, capacitor trenches 52 and ring trenches 15 may be formed simultaneously in a single masking step. Alternately or additionally, isolation trenches 27 and ring trenches 15 may be formed simultaneously in a single masking step. In one embodiment, in a single masking step, (a), (b), (c), and (d) are simultaneously formed, where:
(a): digitline trenches 17 in individual die areas 8;
(b): capacitor trenches 52 in individual die areas 8;
(c): isolation trenches 27 in adjacent region 81; and
(d): a plurality of ring trenches 15 in scribe-line area 9 that individually at least partially surround individual die areas 8.
   The artisan will recognize that in any such embodiments some materials may be commonly (at the same time) deposited into certain different-such-type trenches to save total processing steps and not deposited into certain other different-such-type trenches. Temporary material (e.g., 21; e.g., carbon) may be formed in such certain other different-such-type trenches to preclude such common depositing, with such temporary material later being removed followed by subsequent processing, for example analogous to what occurred with respect to ring trenches 15 when forming digitlines DL in digitline trenches 17.

In another alternate example, by way of example only, and less preferred, temporary material 21 could be removed from occluding initially-formed ring trenches 15 before forming conductive-via openings 86 (not shown; e.g., not forming conductive-via openings 86 as is shown in FIG. 20, but only there removing temporary material 21 from ring trenches 15). Then, initially-formed ring trenches 15 could be extended through insulative material 12 to lower semiconductive material 14L. Such extended ring trenches may or may not extend into lower semiconductive material 14L. Regardless, such extended ring trenches may again be occluded (e.g., filled) with temporary material 21. Conductive-via openings 86 could then be formed. Then, the temporary material 21 would be removed from ring trenches 15. Semiconductive material 14 at the bases of conductive-via openings 86 and vertically between access lines WLt and WLb could be removed before or after removing the temporary material 21 from ring trenches 15. If before, a construction like FIG. 22 will result. If after, ring trenches 15 would not laterally join in lower semiconductive material 14L (not shown) and the conductive cores 39 of the resultant at least two conductive-wall constructions 35 would not be directly against one another in lower semiconductor material 14L (not shown).

Alternate embodiment constructions may result from method embodiments described above, or otherwise. Regardless, embodiments of the invention encompass circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

In one embodiment, memory circuitry (e.g., 4) comprises an integrated circuit die (e.g., 99) comprising a radially-outermost region (e.g., 53) surrounding a radially-inner region (e.g., 8). The radially-inner region comprises a memory-array region (e.g., 80) comprising memory cells (e.g., MC). The radially-outermost region comprises a lower semiconductor material (e.g., 14L), an insulative material (e.g., 12) directly above the lower semiconductor material, and a stack (e.g., 18) comprising alternating tiers of different composition semiconductive materials (e.g., 14, 19) directly above the insulative material. A conductive-wall construction (e.g., 35) is in the radially-outermost region and at least partially surrounds the radially-inner region. The conductive-wall construction extends through the stack and the insulative material to the lower semiconductor material. The conductive-wall construction comprises two laterally-outer regions (e.g., 37) of insulating material (e.g., 40) having a conductive core (e.g., 39) laterally there-between. The conductive core is directly electrically coupled to the lower semiconductor material. Any other attribute(s) or aspect(s) as shown and/or described herein with respect to other embodiments may be used.

In one embodiment, memory circuitry (e.g., 4) comprises an integrated circuit die (e.g., 99) comprising a radially-outermost region (e.g., 53) surrounding a radially-inner region (e.g., 8). The radially-inner region comprises a memory-array region (e.g., 80) and an adjacent region (e.g., 81) horizontally adjacent the memory-array region. The memory-array region comprises vertically-alternating insulative tiers (e.g., 20) and memory-cell tiers (e.g., 22). The memory-cell tiers comprise memory cells (e.g., MC) that individually comprise a horizontal transistor (e.g., T) comprising a gate (e.g., 30*). The gate comprises part of one of a plurality of horizontal conductive access lines (e.g., WL*) that individually directly electrically couple together multiple of the gates of different ones of the horizontal transistors that are in the same memory-cell tier and that extend horizontally from the memory-array region into the adjacent region. The radially-outermost region comprises a lower semiconductor material (e.g., 14L), an insulative material (e.g., 12) directly above the lower semiconductor material, and a stack (e.g., 18) comprising alternating tiers of different composition semiconductive materials (e.g., 14, 19) directly above the insulative material. A conductive-wall construction (e.g., 35) is in the radially-outermost region and at least partially surrounds the radially-inner region. Conductive-via constructions 65 are in the adjacent region and individually directly electrically couple to individual of the access lines. The conductive-wall construction extends through the stack and the insulative material to the lower semiconductor material. The conductive-wall construction comprises two laterally-outer regions (e.g., 37) of insulating material (e.g., 40) having conductive core material (e.g., 68, 69) laterally there-between. The conductive core material is directly electrically coupled to the lower semiconductor material. The conductive-via constructions individually comprise a conductive core (e.g., 39) and a radially-outer insulative lining (e.g., 67) circumferentially there-about. The conductive core is of the same conductive core material as the conductive-wall construction. The radially-outer insulative lining is of the same insulating material as the two laterally-outer regions of the conductive-wall construction. Any other attribute(s) or aspect(s) as shown and/or described herein with respect to other embodiments may be used.

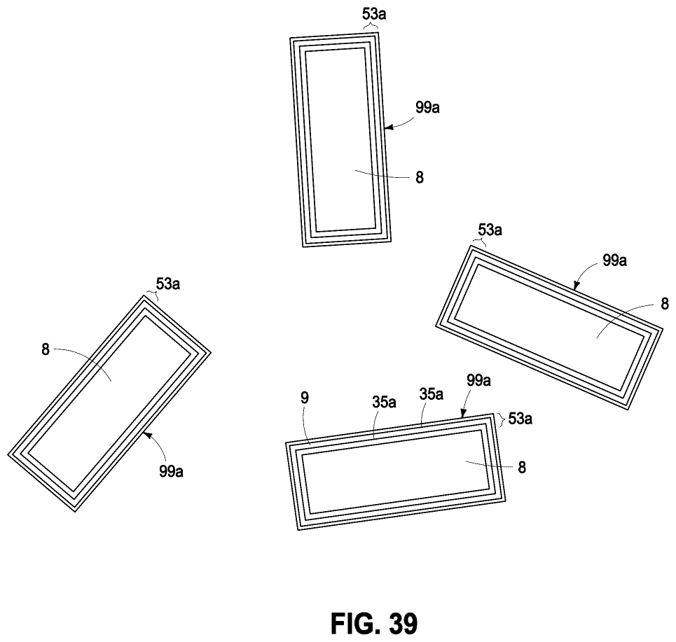

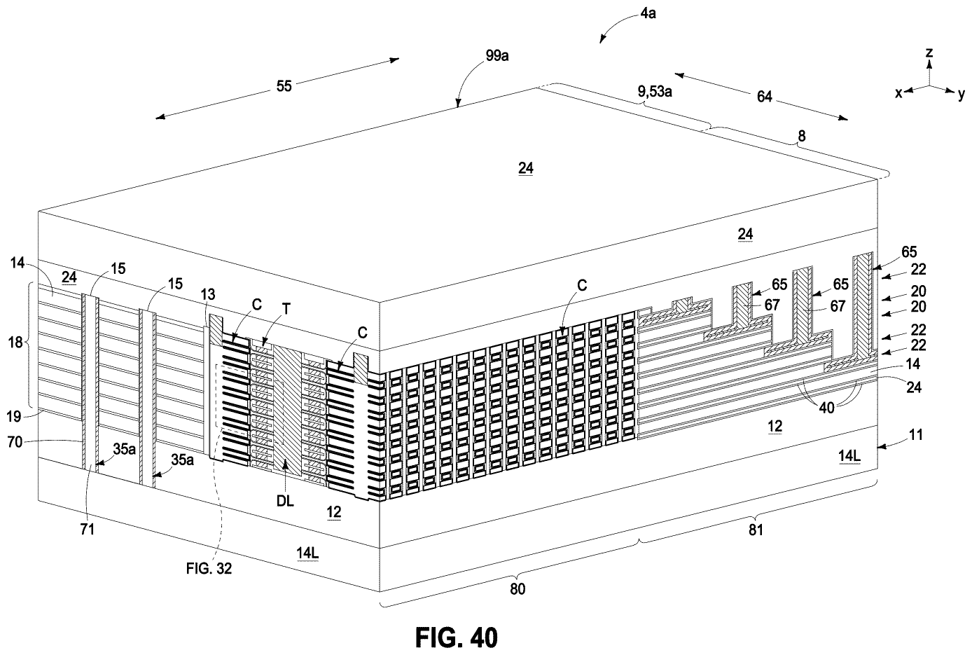

An alternate embodiment construction 4a is shown in FIGS. 39-41. Like numerals from the above-described embodiments have been used where appropriate, with some construction differences being indicated with the suffix “a” or with different numerals. Such memory circuitry (e.g., 4a) comprises an integrated circuit die (e.g., 99a) comprising a radially-outermost region (e.g., 53a) surrounding a radially-inner region (e.g., 8). The radially-inner region comprises a memory-array region (e.g., 80) comprising memory cells (e.g., MC) that individually comprise a capacitor (e.g., C). The radially-outermost region comprises a lower semiconductor material (e.g., 14L), an insulative material (e.g., 12) directly above the lower semiconductor material, a stack (e.g., 18) comprising alternating tiers of different composition semiconductive materials (e.g., 14, 19) directly above the insulative material. A conductive-wall construction (e.g., 35a) is in the radially-outermost region and at least partially surrounds the radially-inner region. The capacitor comprises a conductive storage node electrode (e.g., 33), a conductive cell plate electrode (e.g., 34) comprising conductive material (e.g., 70, 71), and a capacitor insulator (e.g., 36) comprising insulator material there-between. The conductive-wall construction extends through the stack and the insulative material to the lower semiconductor material. The conductive-wall construction comprises two laterally-outer regions (e.g., 37) of insulating material (e.g., 40) having conductive core material (e.g., 70, 71) laterally there-between. The conductive core material is directly electrically coupled to the lower semiconductor material. The conductive core material is of the same conductive material as the cell plate electrode. Such a structure, by way or example and not of limitation, may be fabricated by forming ring trenches 15 and capacitor trenches 52 in the same common masking step, followed by occluding (e.g., filling) the ring trenches with temporary material and removing such just prior to forming conductive material 70 and 71. Any other attribute(s) or aspect(s) as shown and/or described herein with respect to other embodiments may be used.

Conductive-wall constructions as described herein may alleviate electrostatic discharge during fabrication and reduce die cracking during dicing. Heretofore, such were separately fabricated from fabrication within the die area. Combining fabrication of a conductive-wall construction with fabrication of some features within the die area may save mask steps, thereby reducing cost and risk.

The memory circuitry described herein (e.g., conductive vias thereof) may connect with circuitry that is on either the top or the bottom (i.e., either z-axis side) of the stack regardless of orientation of the construction in three-dimensional space and which is not material to aspects of the inventions disclosed herein. For example, and by way of example only, the conductive vias may connect with peripheral control circuitry that is beneath the stack with respect to the orientation shown in the drawings. As an alternate example, and by way of example only, the conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, circuitry components (e.g., below stack 18) may be fabricated relative to the bottom of the stack with respect to the shown orientation but inverted therefrom during processing. Such circuitry components may connect with conductive vias that extend through the stack to the substrate bonded with the other side that has such peripheral control circuitry. Regardless, constructions as shown and described herein may be processed, packaged, and/or mounted in any three-dimensional spatial orientation.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10°of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises fabricating a semiconductor wafer to have die areas to comprise memory cells and to have scribe-line area around individual of the die areas. The scribe-line area comprises a lower semiconductor material. An insulative material is directly above the lower semiconductor material. A stack comprising alternating tiers of different composition semiconductive materials is directly above the insulative material. A plurality of trenches are formed in the scribe-line area that individually at least partially surround the individual die areas. The trenches extend through the stack and the insulative material to the lower semiconductor material. A conductive-wall construction is formed in individual of the trenches and that at least partially surrounds one of the individual die areas. The conductive-wall construction extends through the stack and the insulative material to the lower semiconductor material. The conductive-wall construction comprises two laterally-outer regions of insulating material having a conductive core laterally there-between. The conductive core is directly electrically coupled to the lower semiconductor material.

In some embodiments, a method used in forming memory circuitry comprises fabricating a semiconductor wafer to have die areas to comprise memory cells and to have scribe-line area around individual of the die areas. A plurality of trenches is formed in the scribe-line area and that individually at least partially surround the individual die areas. The die areas are formed to individually comprise a memory-array region and an adjacent region that is horizontally adjacent the memory-array region. The memory-array region comprises vertically-alternating insulative tiers and memory-cell tiers. The memory-cell tiers comprise memory cells that individually comprise a horizontal transistor comprising a gate. The gate comprises part of one of a plurality of horizontal conductive access lines that individually directly electrically couple together multiple of the gates of different ones of the horizontal transistors that are in the same memory-cell tier and extend horizontally from the memory-array region into the adjacent region. Conductive-via openings are formed in the adjacent region and individually extend to have a bottom that is in one of the memory-cell tiers comprising one of the access lines. (a) and (b) are simultaneously formed, where:
(a): two laterally-outer regions of insulating material and a conductive core laterally there-between of a conductive-wall construction in individual of the trenches, the conductive core of the conductive-wall construction being directly electrically coupled to the lower semiconductor material; and
(b): a conductive core and a radially-outer insulative lining circumferentially there-about of a conductive-via construction in individual of the conductive-via openings, the conductive core of the conductive-via construction directly electrically coupling with the one access line.

In some embodiments, a method used in forming memory circuitry comprises fabricating a semiconductor wafer to have die areas and scribe-line area around individual of the die areas. In a single masking step, digitline trenches are simultaneously formed in the individual die areas and a plurality of ring trenches are formed in the scribe-line area that individually at least partially surround the individual die areas. Digitlines are formed in the digitline trenches. A conductive-wall construction is formed in individual of the ring trenches and at least partially surrounds one of the individual die areas. The conductive-wall construction extends through a majority of thickness of the semiconductor wafer and is directly electrically coupled with semiconductive material of the semiconductor wafer. A memory-array region is formed comprising memory cells in the individual die areas. Individual of the memory cells are electrically coupled with individual of the digitlines.

In some embodiments, a method used in forming memory circuitry comprises fabricating a semiconductor wafer to have die areas and scribe-line area around individual of the die areas. In a single masking step, capacitor trenches are simultaneously formed in the individual die areas and a plurality of ring trenches are formed in the scribe-line area that individually at least partially surround the individual die areas. Capacitors are formed in the capacitor trenches. A conductive-wall construction is formed in individual of the ring trenches and that at least partially surrounds one of the individual die areas. The conductive-wall construction extends through a majority of thickness of the semiconductor wafer and is directly electrically coupled with semiconductive material of the semiconductor wafer. A memory-array region is formed comprising memory cells in the individual die areas. Individual of the memory cells comprise one of the capacitors.

In some embodiments, a method used in forming memory circuitry comprises fabricating a semiconductor wafer to have die areas and scribe-line area around individual of the die areas. The individual die areas have a memory-array region to comprise memory cells and an adjacent region that is horizontally adjacent the memory-array region. In a single masking step, isolation trenches are simultaneously formed in the adjacent region and a plurality of ring trenches are formed in the scribe-line area that individually at least partially surround the individual die areas. Insulative material is formed in the isolation trenches. A conductive-wall construction is formed in individual of the ring trenches and that at least partially surrounds one of the individual die areas. The conductive-wall construction extends through a majority of thickness of the semiconductor wafer and is directly electrically coupled with semiconductive material of the semiconductor wafer.

In some embodiments, a method used in forming memory circuitry comprises fabricating a semiconductor wafer to have die areas and scribe-line area around individual of the die areas. The individual die areas have a memory-array region to comprise memory cells and an adjacent region that is horizontally adjacent the memory-array region. In a single masking step, (a), (b), (c), and (d) are simultaneously formed, where:
(a): digitline trenches in the individual die areas;
(b): capacitor trenches in the individual die areas;
(c): isolation trenches in the adjacent region; and
(d): a plurality of ring trenches in the scribe-line area that individually at least partially surround the individual die areas;
   Digitlines are formed in the digitline trenches. Individual of the memory cells are electrically coupled with individual of the digitlines. Capacitors are formed in the capacitor trenches. The individual memory cells comprise one of the capacitors. Insulative material is formed in the isolation trenches. A conductive-wall construction is formed in individual of the ring trenches and that at least partially surrounds one of the individual die areas. The conductive-wall construction extends through a majority of thickness of the semiconductor wafer and is directly electrically coupled with semiconductive material of the semiconductor wafer.

In some embodiments, memory circuitry comprises an integrated circuit die comprising a radially-outermost region surrounding a radially-inner region. The radially-inner region comprises a memory-array region comprising memory cells. The radially-outermost region comprises a lower semiconductor material. An insulative material is directly above the lower semiconductor material. A stack comprising alternating tiers of different composition semiconductive materials is directly above the insulative material. A conductive-wall construction is in the radially-outermost region at least partially surrounding the radially-inner region. The conductive-wall construction extends through the stack and the insulative material to the lower semiconductor material. The conductive-wall construction comprises two laterally-outer regions of insulating material having a conductive core laterally there-between. The conductive core is directly electrically coupled to the lower semiconductor material.

In some embodiments, memory circuitry comprises an integrated circuit die comprising a radially-outermost region surrounding a radially-inner region. The radially-inner region comprises a memory-array region and an adjacent region horizontally adjacent the memory-array region. The memory-array region comprises vertically-alternating insulative tiers and memory-cell tiers. The memory-cell tiers comprise memory cells that individually comprise a horizontal transistor comprising a gate. The gate comprises part of one of a plurality of horizontal conductive access lines that individually directly electrically couple together multiple of the gates of different ones of the horizontal transistors that are in the same memory-cell tier and that extend horizontally from the memory-array region into the adjacent region. The radially-outermost region comprises a lower semiconductor material. An insulative material is directly above the lower semiconductor material. A stack comprising alternating tiers of different composition semiconductive materials is directly above the insulative material. A conductive-wall construction is in the radially-outermost region at least partially surrounding the radially-inner region. Conductive-via constructions are in the adjacent region and are individually directly electrically coupled to individual of the access lines. The conductive-wall construction extends through the stack and the insulative material to the lower semiconductor material. The conductive-wall construction comprises two laterally-outer regions of insulating material having conductive core material laterally there-between. The conductive core material is directly electrically coupled to the lower semiconductor material. The conductive-via constructions individually comprise a conductive core and a radially-outer insulative lining circumferentially there-about. The conductive core is of the same conductive core material as the conductive-wall construction. The radially-outer insulative lining is of the same insulating material as the two laterally-outer regions of the conductive-wall construction.

In some embodiments, memory circuitry comprises an integrated circuit die comprising a radially-outermost region surrounding a radially-inner region. The radially-inner region comprises a memory-array region comprising memory cells that individually comprise a capacitor. The radially-outermost region comprises a lower semiconductor material. An insulative material is directly above the lower semiconductor material. A stack comprises alternating tiers of different composition semiconductive materials directly above the insulative material. A conductive-wall construction is in the radially-outermost region and at least partially surrounds the radially-inner region. The capacitor comprises a conductive storage node electrode, a conductive cell plate electrode comprising conductive material, and a capacitor insulator comprising insulator material there-between. The conductive-wall construction extends through the stack and the insulative material to the lower semiconductor material. The conductive-wall construction comprises two laterally-outer regions of insulating material having conductive core material laterally there-between. The conductive core material is directly electrically coupled to the lower semiconductor material. The conductive core material is of the same conductive material as the cell plate electrode.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. Memory circuitry comprising:
an integrated circuit die comprising a radially-outermost region surrounding a radially-inner region, the radially-inner region comprising a memory-array region comprising memory cells, the radially-outermost region comprising:
a lower semiconductor material;
an insulative material directly above the lower semiconductor material; and
a stack comprising alternating tiers of different composition semiconductive materials directly above the insulative material; and a conductive-wall construction in the radially-outermost region at least partially surrounding the radially-inner region, the conductive-wall construction extending through the stack and the insulative material to the lower semiconductor material, the conductive-wall construction comprising two laterally-outer regions of insulating material having a conductive core laterally there-between, the conductive core being directly electrically coupled to the lower semiconductor material.

2. The memory circuitry of claim 1 wherein the conductive-wall construction completely surrounds the radially-inner region.

3. The memory circuitry of claim 1 wherein the memory cells are vertically stacked in the memory-array region and individually comprise a capacitor and a horizontal transistor.

4. The memory circuitry of claim 1 wherein one of the different composition semiconductive materials comprises silicon and the other comprises a silicon-germanium alloy.

5. The memory circuitry of claim 4 wherein the silicon is at least twice as thick as the silicon-germanium alloy.

6. The memory circuitry of claim 1 wherein the lower semiconductor material comprises silicon.

7. The memory circuitry of claim 1 wherein the insulative material comprises silicon dioxide.

8. The memory circuitry of claim 1 wherein,
the memory cells are vertically stacked in the memory-array region and individually comprise a capacitor and a horizontal transistor;
one of the different composition semiconductive materials comprises silicon and the other comprises a silicon-germanium alloy;
the lower semiconductor material comprises silicon; and
the insulative material comprises silicon dioxide.

9. The memory circuitry of claim 1 wherein the two laterally-outer regions of insulating material terminate above or in the insulative material.

10. The memory circuitry of claim 1 wherein the conductive core comprises two laterally-outer regions of a first conductive material and a laterally-inner region of a second conductive material laterally there-between, the first and second conductive materials being of different compositions relative one another.

11. The memory circuitry of claim 1 comprising two of said conductive-wall construction in the radially-outermost region, the two conductive-wall constructions being laterally spaced from one another in the stack.

12. The memory circuitry of claim 11 wherein the conductive cores of the two conductive-wall constructions are directly against one another in the lower semiconductor material.

13. Memory circuitry comprising:
an integrated circuit die comprising a radially-outermost region surrounding a radially-inner region;
the radially-inner region comprising a memory-array region and an adjacent region horizontally adjacent the memory-array region, the memory-array region comprising vertically-alternating insulative tiers and memory-cell tiers, the memory-cell tiers comprising memory cells that individually comprise a horizontal transistor comprising a gate, the gate comprising part of one of a plurality of horizontal conductive access lines that individually directly electrically couple together multiple of the gates of different ones of the horizontal transistors that are in the same memory-cell tier and that extend horizontally from the memory-array region into the adjacent region;
the radially-outermost region comprising:
a lower semiconductor material;
an insulative material directly above the lower semiconductor material; and
a stack comprising alternating tiers of different composition semiconductive materials directly above the insulative material; a conductive-wall construction in the radially-outermost region at least partially surrounding the radially-inner region;
conductive-via constructions in the adjacent region that individually directly electrically couple to individual of the access lines;
the conductive-wall construction extending through the stack and the insulative material to the lower semiconductor material, the conductive-wall construction comprising two laterally-outer regions of insulating material having conductive core material laterally there-between, the conductive core material being directly electrically coupled to the lower semiconductor material; and
the conductive-via constructions individually comprising a conductive core and a radially-outer insulative lining circumferentially there-about, the conductive core being of the same conductive core material as the conductive-wall construction, the radially-outer insulative lining being of the same insulating material as the two laterally-outer regions of the conductive-wall construction.

14. The memory circuitry of claim 13 wherein the conductive core material comprises first and second conductive materials that are of different compositions relative one another.

15. The memory circuitry of claim 14 wherein,
in the conductive-wall construction, the first conductive material is in two laterally-outer regions that are laterally outward of a laterally-inner region of the second conductive material; and
in the conductive-via constructions, the first conductive material is in a radially-outer region that is directly against the radially-outer insulative lining and is radially outward of the second conductive material.

16. The memory circuitry of claim 15 wherein the first conductive material is titanium nitride and the second conductive material is elemental tungsten.

17. The memory circuitry of claim 16 wherein the insulating material is silicon nitride.

18. The memory circuitry of claim 13 wherein the two laterally-outer regions of insulating material terminate above or in the insulative material.

19. Memory circuitry comprising:
an integrated circuit die comprising a radially-outermost region surrounding a radially-inner region;
the radially-inner region comprising a memory-array region comprising memory cells that individually comprise a capacitor;
the radially-outermost region comprising:
a lower semiconductor material;
an insulative material directly above the lower semiconductor material; and
a stack comprising alternating tiers of different composition semiconductive materials directly above the insulative material; a conductive-wall construction in the radially-outermost region at least partially surrounding the radially-inner region;
the capacitor comprising a conductive storage node electrode, a conductive cell plate electrode comprising conductive material, and a capacitor insulator comprising insulator material there-between; and
the conductive-wall construction extending through the stack and the insulative material to the lower semiconductor material, the conductive-wall construction comprising two laterally-outer regions of insulating material having conductive core material laterally there-between, the conductive core material being directly electrically coupled to the lower semiconductor material, the conductive core material being of the same conductive material as the cell plate electrode.

20. The memory circuitry of claim 19 wherein the conductive material comprises conductively-doped semiconductive material.

21. The memory circuitry of claim 20 wherein the conductively-doped semiconductive material is a boron-doped silicon-germanium alloy.
